(19) United States
(12) Patent Application Publication
(10) Pub. No.: US 2003/0020069 A1
(43) Pub. Date: Jan. 30, 2003

(54) Structure and method for optimizing transmission media through dielectric layering and doping in semiconductor structures and devices utilizing the formation of a compliant substrate

(75) Inventors: John E. Holmes, Scottsdale, AZ (US); Bruce Allen Bosco, Phoenix, AZ (US); Rudy M. Emrick, Gilbert, AZ (US); Steven James Franson, Scottsdale, AZ (US); Nestor Javier Escalera, Gilbert, AZ (US); Stephen Kent Rockwell, Mesa, AZ (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/911,459

(22) Filed: Jul. 25, 2001

(51) Int. Cl. H01L 31/0256; H01L 29/47

(52) U.S. Cl. 257/76; 257/73

(57) ABSTRACT

High quality epitaxial layers of monocrystalline materials can be grown overlying monocrystalline substrates such as large silicon wafers by forming a compliant substrate for growing the monocrystalline layers. An accommodating buffer layer comprises a layer of monocrystalline oxide spaced apart from a silicon wafer by an amorphous interface layer of silicon oxide. The amorphous interface layer dissipates strain and permits the growth of a high quality monocrystalline oxide accommodating buffer layer. The accommodating buffer layer is lattice matched to both the underlying silicon wafer and the overlying monocrystalline material layer. Any lattice mismatch between the accommodating buffer layer and the underlying silicon substrate is taken care of by the amorphous interface layer. In addition, formation of a compliant substrate may include utilizing surfactant enhanced epitaxy, epitaxial growth of single crystal silicon onto single crystal oxide, and epitaxial growth of Zintl phase materials. A variety of transmission media are disclosed which capitalize on the materials and devices disclosed herein.

### FIELD OF THE INVENTION

This invention relates generally to semiconductor structures and devices and to a method for their fabrication, and more specifically to semiconductor structures and 10 devices and to the fabrication and use of semiconductor structures, devices, and integrated circuits that include a monocrystalline material layer comprised of semiconductor material, compound semiconductor material, and/or other types of material such as metals and non-metals. More particularly this invention relates to structure and methods for transmission media.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and band gap of semiconductive layers improves as the crystallinity of the layer increases. Similarly, the free electron concentration of conductive layers and the electron charge displacement and electron energy recoverability of insulative or dielectric films improves as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material was available at low cost, a variety of semiconductor devices could advantageously be fabricated in or using that film at a low cost compared to the cost of fabricating such devices beginning with a bulk wafer of semiconductor material or in an epitaxial film of such material on a bulk wafer of semiconductor material. In addition, if a thin film of high quality monocrystalline material could be realized beginning with a bulk wafer such as a silicon wafer, an integrated device structure could be achieved that took advantage of the best properties of both the silicon and the high quality monocrystalline material.

For example, transmission media in semiconductor devices could be tailored to particular requirements of a system or signal path. It is known to form microstrip, strip line and coplanar waveguides in and on a semiconductor device. Silicon materials, however, are lossy, especially at radio and optical frequencies. An integrated device structure including both silicon and compound semiconductor devices would benefit from tailored transmission media with physical and electrical properties chosen for particular circuit and device requirements.

Accordingly, a need exists for a semiconductor structure that provides a high quality monocrystalline film or layer over another monocrystalline material and for a process for making such a structure. Further, a need exists for optimized transmission media for use in circuits of such a semiconductor structure.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer; FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention; and

FIGS. 21-23 illustrate schematically, in cross-section, the formation of yet another embodiment of a device structure in accordance with the invention.

FIGS. 24, 25 illustrate schematically, in cross section, device structures that can be used in accordance with various embodiments of the invention.

FIGS. 26-30 include illustrations of cross-sectional views of a portion of an integrated circuit that includes a compound semiconductor portion, a bipolar portion, and an MOS portion in accordance with what is shown herein.

FIGS. 31-37 include illustrations of cross-sectional views of a portion of another integrated circuit that includes a semiconductor laser and a MOS transistor in accordance with what is shown herein.

FIG. 38 shows a cross section of a first embodiment of a semiconductor structure including a microstrip transmission line.

FIG. 39 shows a cross section of a second embodiment of a semiconductor structure including a microstrip transmission line.

FIG. 40 shows a cross section of a first embodiment of a semiconductor structure including a coplanar waveguide.

FIG. 41 shows a cross section of a second embodiment of a semiconductor structure including a coplanar waveguide.

FIG. 42 shows a cross section of a third embodiment of a semiconductor structure including a coplanar waveguide.

FIG. 43 shows a cross section of a fourth embodiment of a semiconductor structure including a coplanar waveguide.

FIG. 44 shows a cross section of a fifth embodiment of a semiconductor structure including a coplanar waveguide.

FIG. 45 shows a cross section of a semiconductor structure including a suspended-substrate microstrip line.

FIG. 46 shows a cross section of a semiconductor structure including an inverted suspended-substrate microstrip line.

FIG. 47 shows a cross section of a semiconductor structure including a parallel inverted suspended-substrate microstrip line.

FIG. 48 shows a cross section of a first embodiment of a semiconductor structure including a strip line.

FIG. 49 shows a cross section of a second embodiment of a semiconductor structure including a strip line.

FIG. 50 shows a cross section of a third embodiment of a semiconductor structure including a strip line.

FIG. 51 shows a cross section of a semiconductor structure including a dielectric-filled waveguide.

FIG. 52 shows a cross section of a semiconductor structure including a trapped image line.

FIG. 53 shows a cross section of the semiconductor structure including a trapped image line of FIG. 52 taken along line 53-53′ in FIG. 52.

FIG. 54 shows a top view of the semiconductor structure including a trapped image line of FIG. 52.

FIG. 55 shows a cross section of a semiconductor structure including a rectangular coaxial waveguide.

FIG. 56 shows a cross section of a semiconductor structure including a cylindrical coaxial waveguide.

FIG. 57 shows a cross section of a semiconductor structure including a quasi-cylindrical coaxial waveguide.

FIG. 58 shows a cross section of a semiconductor structure including a vertical coaxial waveguide.

FIG. 59 shows a top view of the semiconductor structure including a vertical coaxial waveguide of FIG. 58.

FIG. 60 shows a bottom view of the semiconductor structure including a vertical coaxial waveguide of FIG. 58.

FIG. 61 shows a cross section of a first embodiment of a semiconductor structure including a variable impedance transmission line.

FIG. 62 shows a cross section of a second embodiment of a semiconductor structure including a variable impedance transmission line.

FIG. 63 shows a cross section of a third embodiment of a semiconductor structure including a variable impedance transmission line.

FIG. 64 shows a cross section of a semiconductor structure including a vertical four way combiner.

FIG. 65 shows a top view of the semiconductor structure including a vertical four way combiner of FIG. 64.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention. Further, among the several sheets of the drawing, like reference numerals identify like elements.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

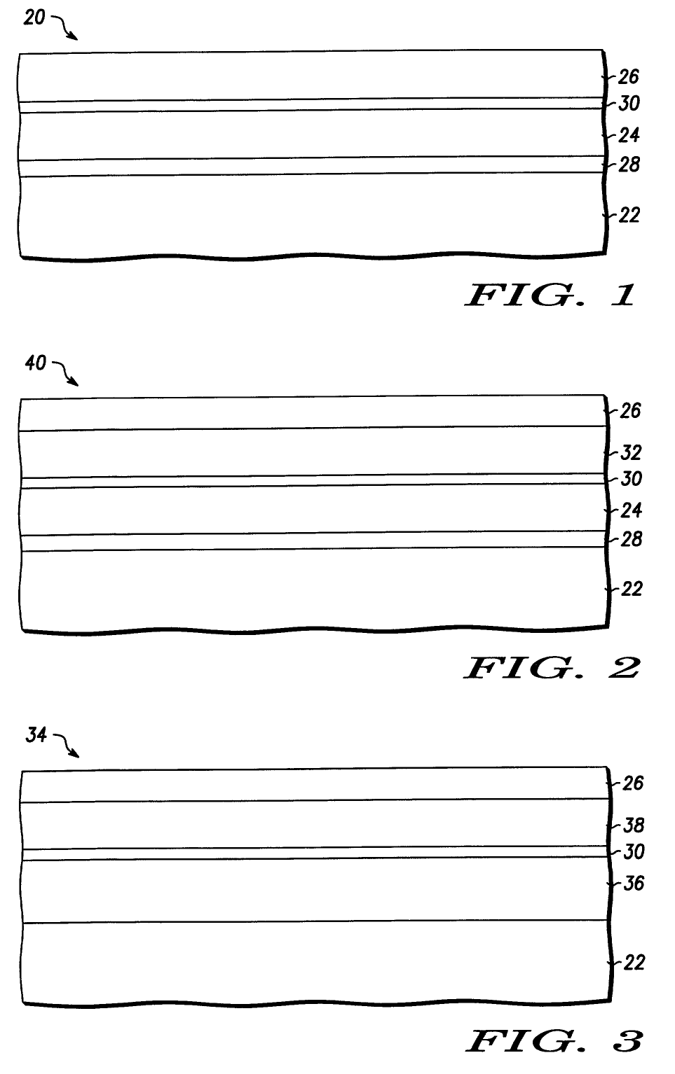

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer. FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O.

By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 μm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

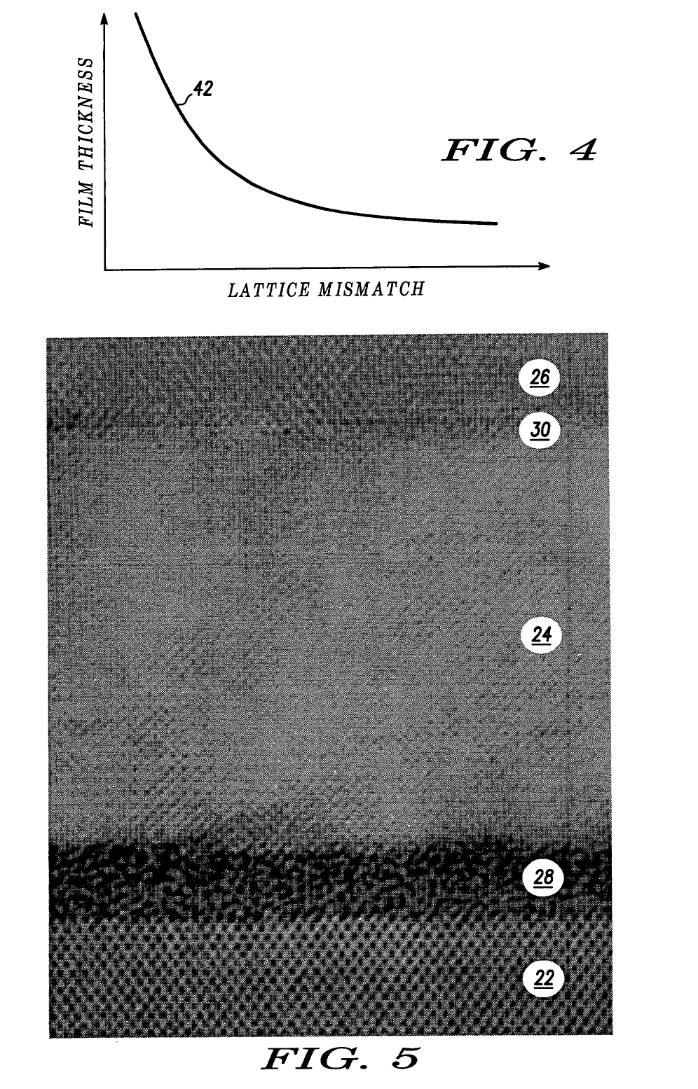

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

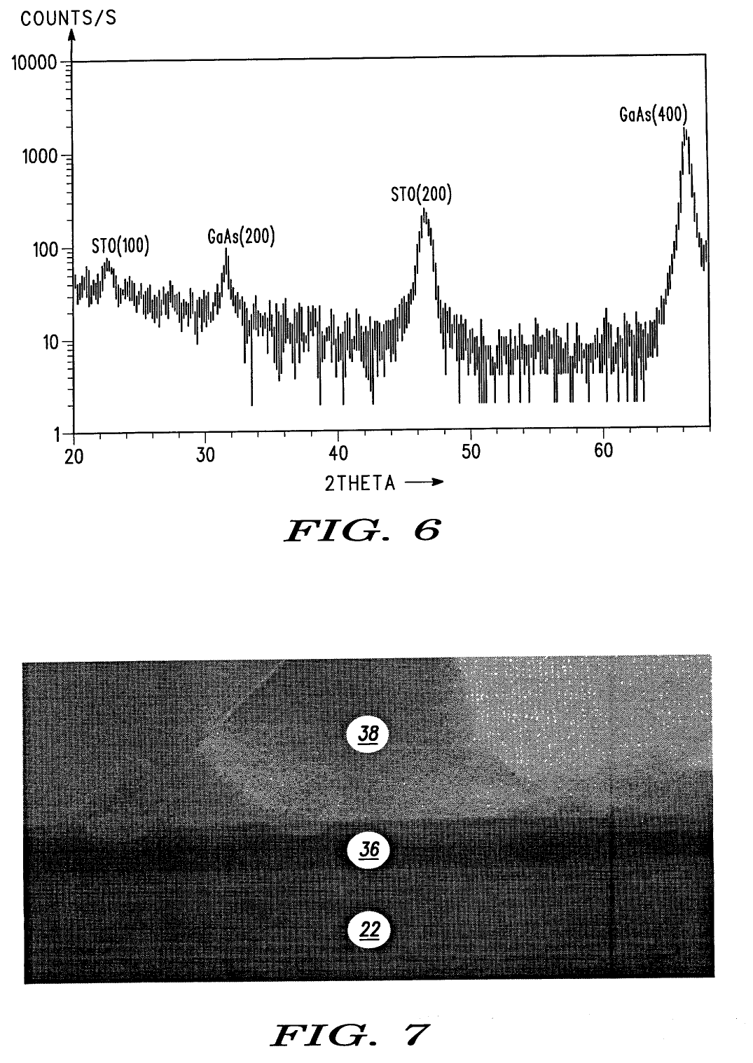

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

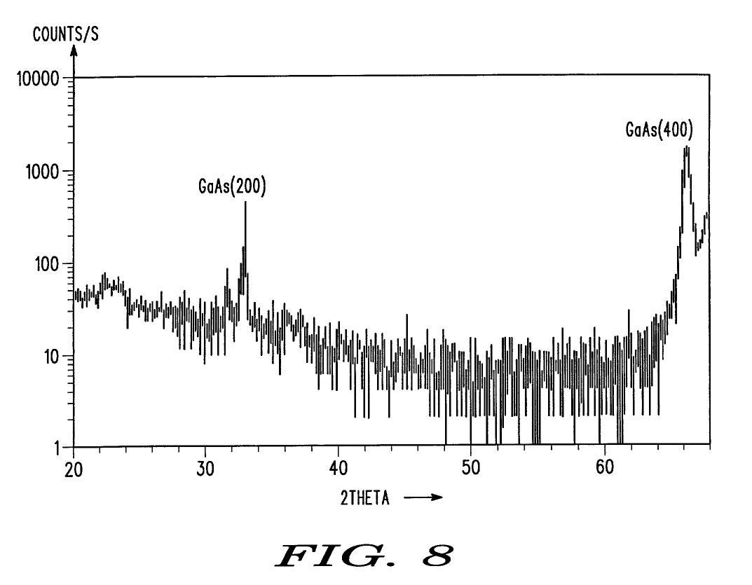

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates, alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

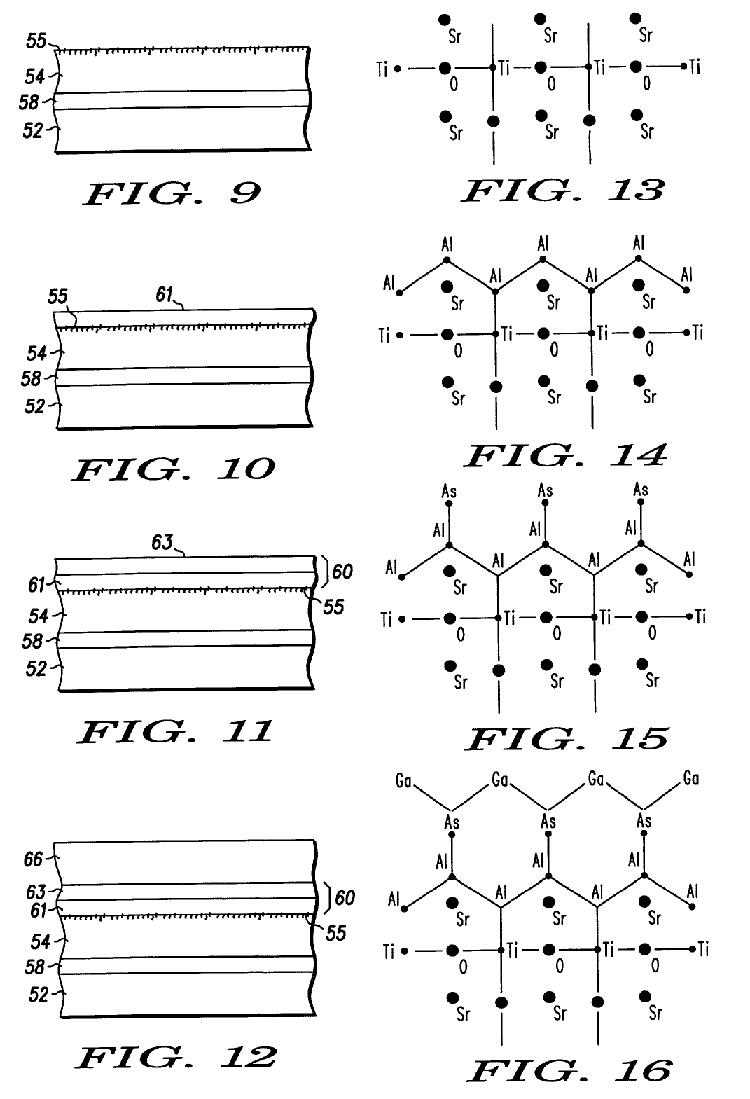

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12. FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GsAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

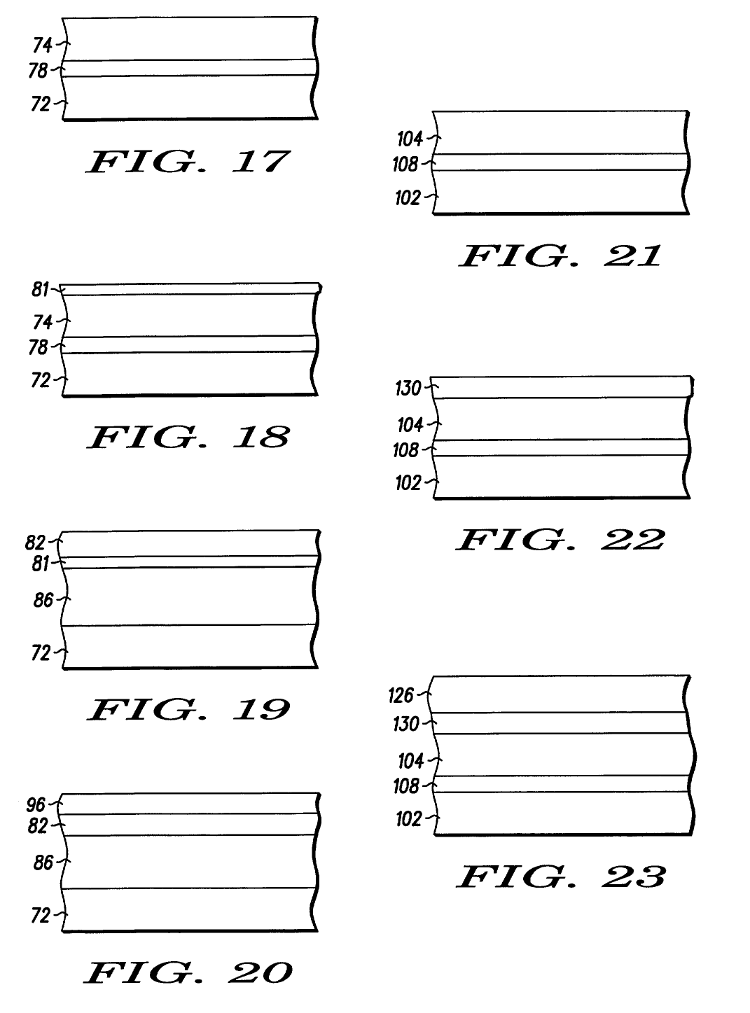

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous intermediate layer 108 is grown on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters. By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

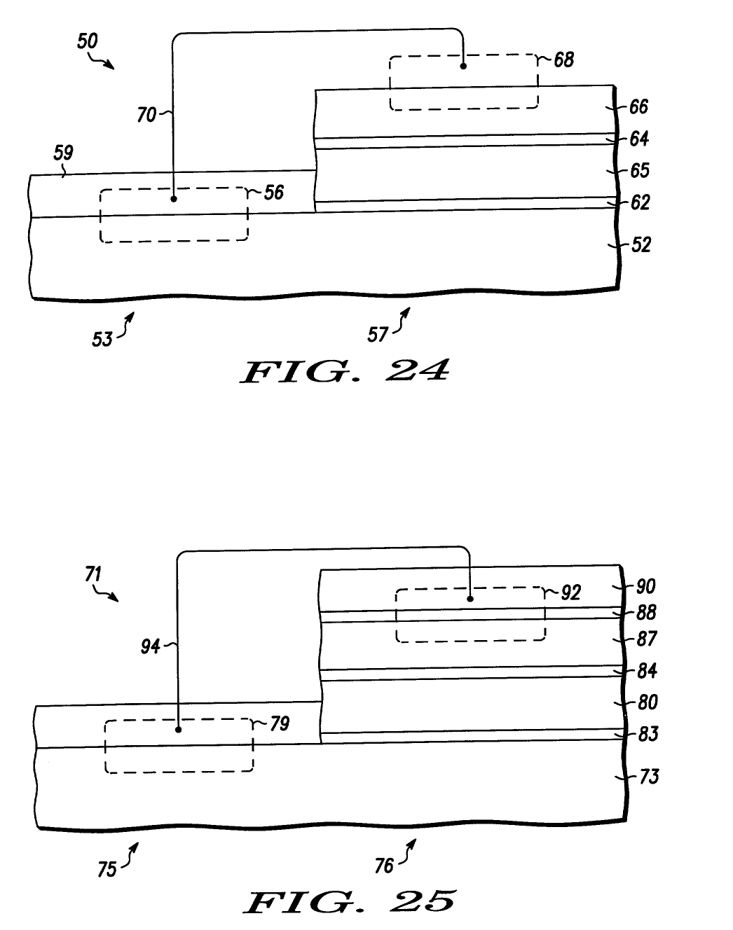

FIG. 24 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. An electrical semiconductor component generally indicated by the dashed line 56 is formed, at least partially, in region 53. Electrical component 56 can be a resistor, a capacitor, an active semiconductor component such as a diode or a transistor or an integrated circuit such as a CMOS integrated circuit. For example, electrical semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie electrical semiconductor component 56. Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer of barium or barium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including barium, titanium and oxygen are deposited onto the template layer to form the monocrystalline oxide layer. Initially during the deposition the partial pressure of oxygen is kept near the minimum necessary to fully react with the barium and titanium to form monocrystalline barium titanate layer. The partial pressure of oxygen is then increased to provide an overpressure of oxygen and to allow oxygen to diffuse through the growing monocrystalline oxide layer. The oxygen diffusing through the barium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a second template layer 64, which can be 110 monolayers of titanium, barium, barium and oxygen, or titanium and oxygen. A layer 66 of a monocrystalline compound semiconductor material is then deposited overlying second template layer 64 by a process of molecular beam epitaxy. The deposition of layer 66 is initiated by depositing a layer of arsenic onto template 64. This initial step is followed by depositing gallium and arsenic to form monocrystalline gallium arsenide 66. Alternatively, strontium can be substituted for barium in the above example.

In accordance with a further embodiment, a semiconductor component, generally indicated by a dashed line 68 is formed in compound semiconductor layer 66.

Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a barium (or strontium) titanate layer 65 and a gallium arsenide layer 66, similar devices can be fabricated using other substrates, monocrystalline oxide layers and other compound semiconductor layers as described elsewhere in this disclosure.

FIG. 25 illustrates a semiconductor structure 71 in accordance with a further embodiment. Structure 71 includes a monocrystalline semiconductor substrate 73 such as a monocrystalline silicon wafer that includes a region 75 and a region 76. An electrical component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 86 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 86 and 90 are formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

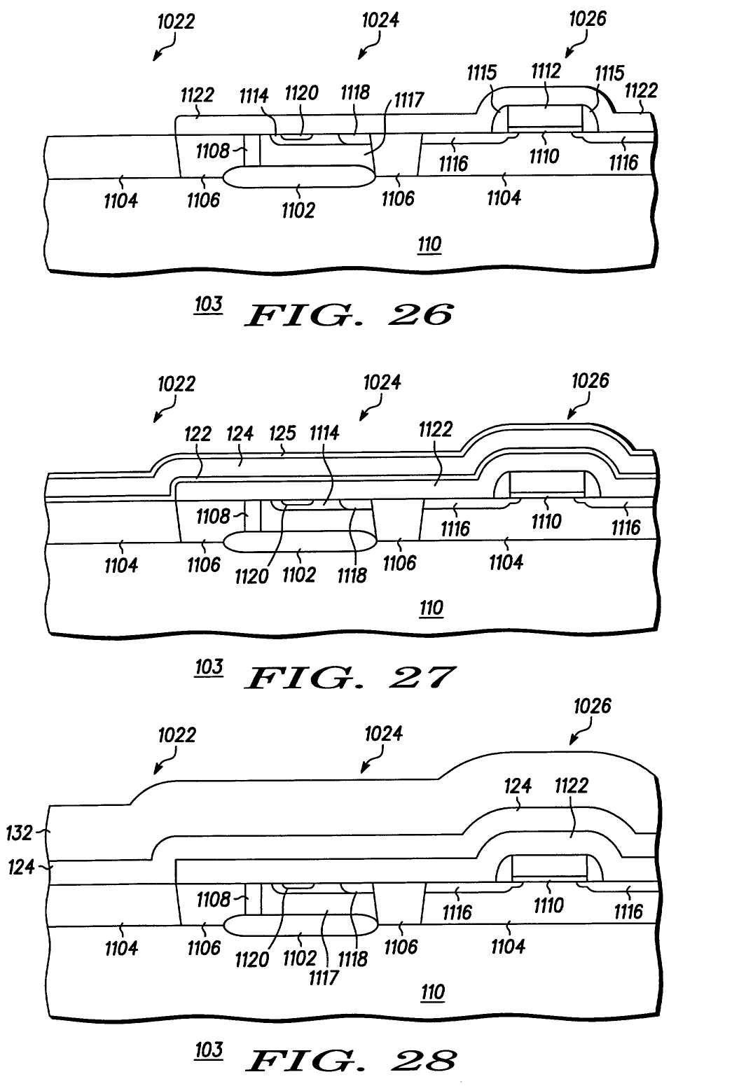

Attention is now directed to a method for forming exemplary portions of illustrative composite semiconductor structures or composite integrated circuits like 50 or 71. In particular, the illustrative composite semiconductor structure or integrated circuit 103 shown in FIGS. 26-30 includes a compound semiconductor portion 1022, a bipolar portion 1024, and a MOS portion 1026. In FIG. 26, a p-type doped, monocrystalline silicon substrate 110 is provided having a compound semiconductor portion 1022, a bipolar portion 1024, and an MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and a N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided for the subsequent processing of this portion, for example in the manner set forth above.

An accommodating buffer layer 124 is then formed over the substrate 110 as illustrated in FIG. 27. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 5-15 nm thick. During the formation of the accommodating buffer layer, an amorphous intermediate layer 122 is formed along the uppermost silicon surfaces of the integrated circuit 103. This amorphous intermediate layer 122 typically includes an oxide of silicon and has a thickness and range of approximately 1-5 nm. In one particular embodiment, the thickness is approximately 2 nm. Following the formation of the accommodating buffer layer 124 and the amorphous intermediate layer 122, a template layer 125 is then formed and has a thickness in a range of approximately one to ten monolayers of a material. In one particular embodiment, the material includes titanium-arsenic, strontium-oxygen-arsenic, or other similar materials as previously described with respect to FIGS. 1-5.

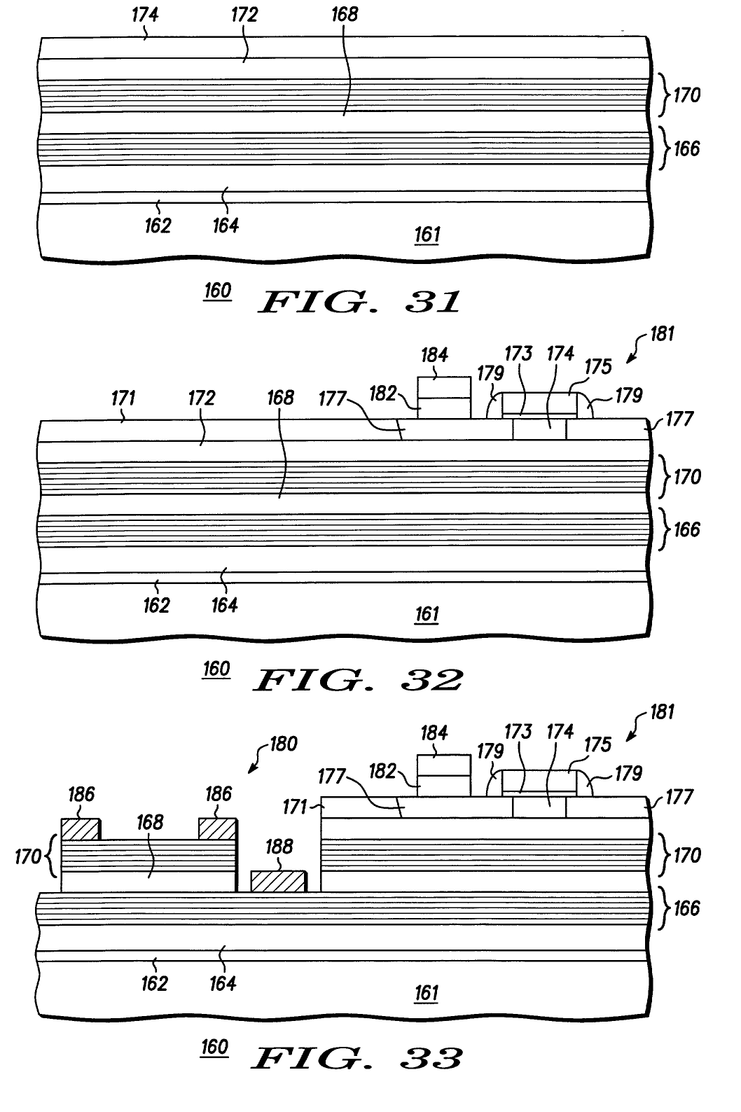

A monocrystalline compound semiconductor layer 132 is then epitaxially grown overlying the monocrystalline portion of accommodating buffer layer 124 as shown in FIG. 28. The portion of layer 132 that is grown over portions of layer 124 that are not monocrystalline may be polycrystalline or amorphous. The compound semiconductor layer can be formed by a number of methods and typically includes a material such as gallium arsenide, aluminum gallium arsenide, indium phosphide, or other compound semiconductor materials as previously mentioned. The thickness of the layer is in a range of approximately 1-5,000 nm, and more preferably 100-2000 nm. Furthermore, additional monocrystalline layers may be formed above layer 132 as discussed in more detail in connection with FIGS. 31-32.

In this particular embodiment, each of the elements within the template layer are also present in the accommodating buffer layer 124, the monocrystalline compound semiconductor material 132, or both. Therefore, the delineation between the template layer 125 and its two immediately adjacent layers disappears during processing. Therefore, when a transmission electron microscopy (TEM) photograph is taken, an interface between the accommodating buffer layer 124 and the monocrystalline compound semiconductor layer 132 is seen.

After at least a portion of layer 132 is formed in region 1022, layers 122 and 124 may be subject to an annealing process as described above in connection FIG. 3 to form a single amorphous accommodating layer. If only a portion of layer 132 is formed prior to the anneal process, the remaining portion may be deposited onto structure 103 prior to further processing.

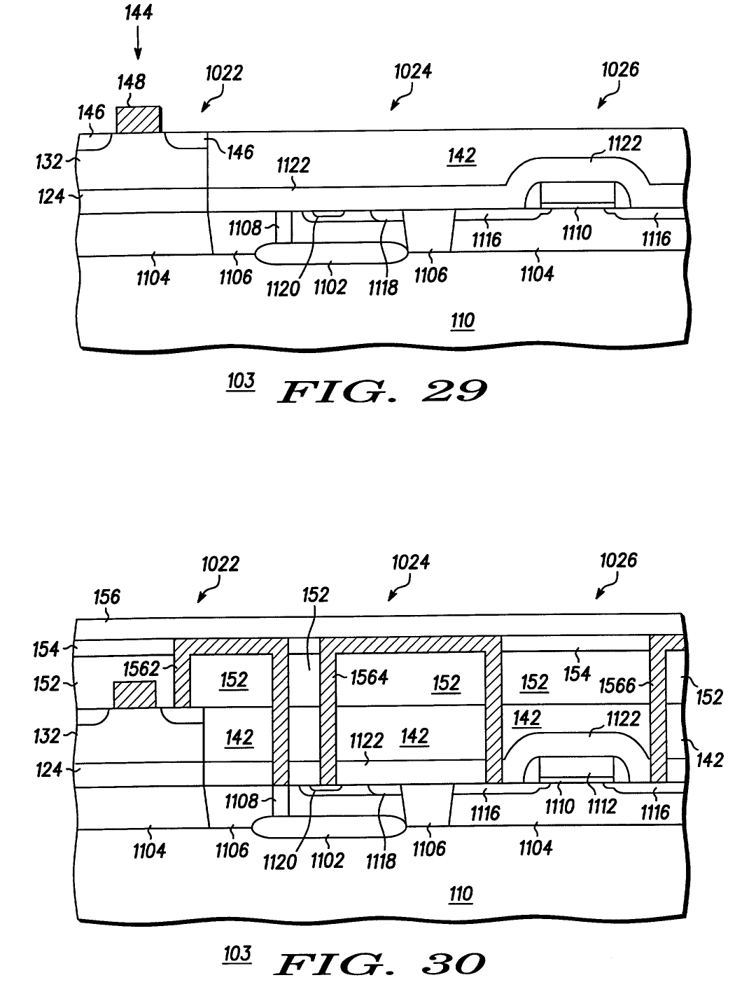

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 29. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished, or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

Processing continues to form a substantially completed integrated circuit 103 as illustrated in FIG. 30. An insulating layer 152 is formed over the substrate 110. The insulating layer 152 may include an etch-stop or polish-stop region that is not illustrated in FIG. 30. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 30, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

In still another embodiment, an integrated circuit can be formed such that it includes an optical laser in a compound semiconductor portion and an optical interconnect (waveguide) to a MOS transistor within a Group IV semiconductor region of the same integrated circuit. FIGS. 31-37 include illustrations of one embodiment.

FIG. 31 includes an illustration of a cross-section view of a portion of an integrated circuit 160 that includes a monocrystalline silicon wafer 161. An amorphous intermediate layer 162 and an accommodating buffer layer 164, similar to those previously described, have been formed over wafer 161. Layers 162 and 164 may be subject to an annealing process as described above in connection with FIG. 3 to form a single amorphous accommodating layer. In this specific embodiment, the layers needed to form the optical laser will be formed first, followed by the layers needed for the MOS transistor. In FIG. 31, the lower mirror layer 166 includes alternating layers of compound semiconductor materials. For example, the first, third, and fifth films within the optical laser may include a material such as gallium arsenide, and the second, fourth, and sixth films within the lower mirror layer 166 may include aluminum gallium arsenide or vice versa. Layer 168 includes the active region that will be used for photon generation. Upper mirror layer 170 is formed in a similar manner to the lower mirror layer 166 and includes alternating films of compound semiconductor materials. In one particular embodiment, the upper mirror layer 170 may be p-type doped compound semiconductor materials, and the lower mirror layer 166 may be n-type doped compound semiconductor materials.

Another accommodating buffer layer 172, similar to the accommodating buffer layer 164, is formed over the upper mirror layer 170. In an alternative embodiment, the accommodating buffer layers 164 and 172 may include different materials. However, their function is essentially the same in that each is used for making a transition between a compound semiconductor layer and a monocrystalline Group IV semiconductor layer. Layer 172 may be subject to an annealing process as described above in connection with FIG. 3 to form an amorphous accommodating layer. A monocrystalline Group IV semiconductor layer 174 is formed over the accommodating buffer layer 172. In one particular embodiment, the monocrystalline Group IV semiconductor layer 174 includes germanium, silicon germanium, silicon germanium carbide, or the like.

In FIG. 32, the MOS portion is processed to form electrical components within this upper monocrystalline Group IV semiconductor layer 174. As illustrated in FIG. 32, a field isolation region 171 is formed from a portion of layer 174. A gate dielectric layer 173 is formed over the layer 174, and a gate electrode 175 is formed over the gate dielectric layer 173. Doped regions 177 are source, drain, or source/drain regions for the transistor 181, as shown. Sidewall spacers 179 are formed adjacent to the vertical sides of the gate electrode 175. Other components can be made within at least a part of layer 174. These other components include other transistors (n-channel or p-channel), capacitors, transistors, diodes, and the like.

A monocrystalline Group IV semiconductor layer is epitaxially grown over one of the doped regions 177. An upper portion 184 is P⁺ doped, and a lower portion 182 remains substantially intrinsic (undoped) as illustrated in FIG. 32. The layer can be formed using a selective epitaxial process. In one embodiment, an insulating layer (not shown) is formed over the transistor 181 and the field isolation region 171. The insulating layer is patterned to define an opening that exposes one of the doped regions 177. At least initially, the selective epitaxial layer is formed without dopants. The entire selective epitaxial layer may be intrinsic, or a p-type dopant can be added near the end of the formation of the selective epitaxial layer. If the selective epitaxial layer is intrinsic, as formed, a doping step may be formed by implantation or by furnace doping. Regardless how the P⁺ upper portion 184 is formed, the insulating layer is then removed to form the resulting structure shown in FIG. 32.

The next set of steps is performed to define the optical laser 180 as illustrated in FIG. 33. The field isolation region 171 and the accommodating buffer layer 172 are removed over the compound semiconductor portion of the integrated circuit. Additional steps are performed to define the upper mirror layer 170 and active layer 168 of the optical laser 180. The sides of the upper mirror layer 170 and active layer 168 are substantially coterminous.

Contacts 186 and 188 are formed for making electrical contact to the upper mirror layer 170 and the lower mirror layer 166, respectively, as shown in FIG. 33. Contact 186 has an annular shape to allow light (photons) to pass out of the upper mirror layer 170 into a subsequently formed optical waveguide.

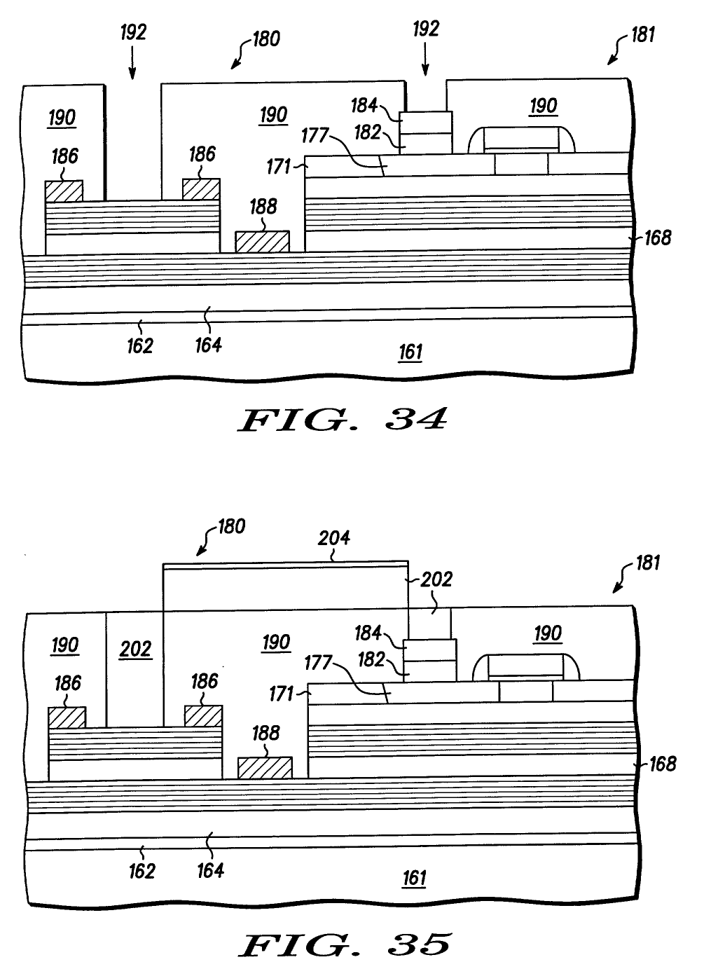

An insulating layer 190 is then formed and patterned to define optical openings extending to the contact layer 186 and one of the doped regions 177 as shown in FIG. 34. The insulating material can be any number of different materials, including an oxide, nitride, oxynitride, low-k dielectric, or any combination thereof. After defining the openings 192, a higher refractive index material 202 is then formed within the openings to fill them and to deposit the layer over the insulating layer 190 as illustrated in FIG. 35. With respect to the higher refractive index material 202, “higher” is in relation to the material of the insulating layer 190 (i.e., material 202 has a higher refractive index compared to the insulating layer 190). Optionally, a relatively thin lower refractive index film (not shown) could be formed before forming the higher refractive index material 202. A hard mask layer 204 is then formed over the high refractive index layer 202. Portions of the hard mask layer 204, and high refractive index layer 202 are removed from portions overlying the opening and to areas closer to the sides of FIG. 35.

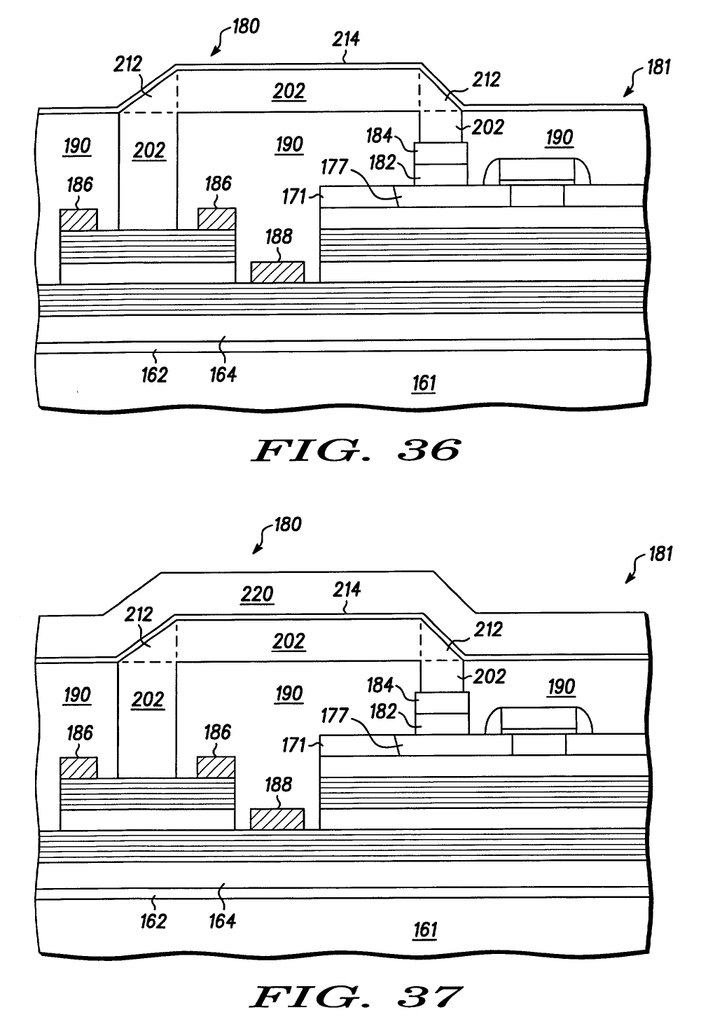

The balance of the formation of the optical waveguide, which is an optical interconnect, is completed as illustrated in FIG. 36. A deposition procedure (possibly a dep-etch process) is performed to effectively create sidewalls sections 212. In this embodiment, the sidewall sections 212 are made of the same material as material 202. The hard mask layer 204 is then removed, and a low refractive index layer 214 (low relative to material 202 and layer 212) is formed over the higher refractive index material 212 and 202 and exposed portions of the insulating layer 190. The dash lines in FIG. 36 illustrate the border between the high refractive index materials 202 and 212. This designation is used to identify that both are made of the same material but are formed at different times.

Processing is continued to form a substantially completed integrated circuit as illustrated in FIG. 37. A passivation layer 220 is then formed over the optical laser 180 and MOSFET transistor 181. Although not shown, other electrical or optical connections are made to the components within the integrated circuit but are not illustrated in FIG. 37. These interconnects can include other optical waveguides or may include metallic interconnects.

In other embodiments, other types of lasers can be formed. For example, another type of laser can emit light (photons) horizontally instead of vertically. If light is emitted horizontally, the MOSFET transistor could be formed within the substrate 161, and the optical waveguide would be reconfigured, so that the laser is properly coupled (optically connected) to the transistor. In one specific embodiment, the optical waveguide can include at least a portion of the accommodating buffer layer. Other configurations are possible.

Clearly, these embodiments of integrated circuits having compound semiconductor portions and Group IV semiconductor portions, are meant to illustrate what can be done and are not intended to be exhaustive of all possibilities or to limit what can be done. There is a multiplicity of other possible combinations and embodiments. For example, the compound semiconductor portion may include light emitting diodes, photodetectors, diodes, or the like, and the Group IV semiconductor can include digital logic, memory arrays, and most structures that can be formed in conventional MOS integrated circuits. By using what is shown and described herein, it is now simpler to integrate devices that work better in compound semiconductor materials with other components that work better in Group IV semiconductor materials. This allows a device to be shrunk, the manufacturing costs to decrease, and yield and reliability to increase.

Although not illustrated, a monocrystalline Group IV wafer can be used in forming only compound semiconductor electrical components over the wafer. In this manner, the wafer is essentially a “handle” wafer used during the fabrication of the compound semiconductor electrical components within a monocrystalline compound semiconductor layer overlying the wafer. Therefore, electrical components can be formed within III-V or II-VI semiconductor materials over a wafer of at least approximately 200 millimeters in diameter and possibly at least approximately 300 millimeters.

By the use of this type of substrate, a relatively inexpensive “handle” wafer overcomes the fragile nature of the compound semiconductor wafers by placing them over a relatively more durable and easy to fabricate base material. Therefore, an integrated circuit can be formed such that all electrical components, and particularly all active electronic devices, can be formed within the compound semiconductor material even though the substrate itself may include a Group IV semiconductor material. Fabrication costs for compound semiconductor devices should decrease because larger substrates can be processed more economically and more readily, compared to the relatively smaller and more fragile, conventional compound semiconductor wafers.

A composite integrated circuit may include components that provide electrical isolation when electrical signals are applied to the composite integrated circuit. The composite integrated circuit may include a pair of optical components, such as an optical source component and an optical detector component. An optical source component may be a light generating semiconductor device, such as an optical laser (e.g., the optical laser illustrated in FIG. 33), a photo emitter, a diode, etc. An optical detector component may be a light-sensitive semiconductor junction device, such as a photodetector, a photodiode, a bipolar junction, a transistor, etc.

A composite integrated circuit may include processing circuitry that is formed at least partly in the Group IV semiconductor portion of the composite integrated circuit. The processing circuitry is configured to communicate with circuitry external to the composite integrated circuit. The processing circuitry may be electronic circuitry, such as a microprocessor, RAM, logic device, decoder, etc.

For the processing circuitry to communicate with external electronic circuitry, the composite integrated circuit may be provided with electrical signal connections with the external electronic circuitry. The composite integrated circuit may have internal optical communications connections for connecting the processing circuitry in the composite integrated circuit to the electrical connections with the external circuitry. Optical components in the composite integrated circuit may provide the optical communications connections which may electrically isolate the electrical signals in the communications connections from the processing circuitry. Together, the electrical and optical communications connections may be for communicating information, such as data, control, timing, etc.

A pair of optical components (an optical source component and an optical detector component) in the composite integrated circuit may be configured to pass information. Information that is received or transmitted between the optical pair may be from or for the electrical communications connection between the external circuitry and the composite integrated circuit. The optical components and the electrical communications connection may form a communications connection between the processing circuitry and the external circuitry while providing electrical isolation for the processing circuitry. If desired, a plurality of optical component pairs may be included in the composite integrated circuit for providing a plurality of communications connections and for providing isolation. For example, a composite integrated circuit receiving a plurality of data bits may include a pair of optical components for communication of each data bit.

In operation, for example, an optical source component in a pair of components may be configured to generate light (e.g., photons) based on receiving electrical signals from an electrical signal connection with the external circuitry. An optical detector component in the pair of components may be optically connected to the source component to generate electrical signals based on detecting light generated by the optical source component. Information that is communicated between the source and detector components may be digital or analog.

If desired the reverse of this configuration may be used. An optical source component that is responsive to the on-board processing circuitry may be coupled to an optical detector component to have the optical source component generate an electrical signal for use in communications with external circuitry. A plurality of such optical component pair structures may be used for providing two-way connections. In some applications where synchronization is desired, a first pair of optical components may be coupled to provide data communications and a second pair may be coupled for communicating synchronization information.

For clarity and brevity, optical detector components that are discussed below are discussed primarily in the context of optical detector components that have been formed in a compound semiconductor portion of a composite integrated circuit. In application, the optical detector component may be formed in many suitable ways (e.g., formed from silicon, etc.).

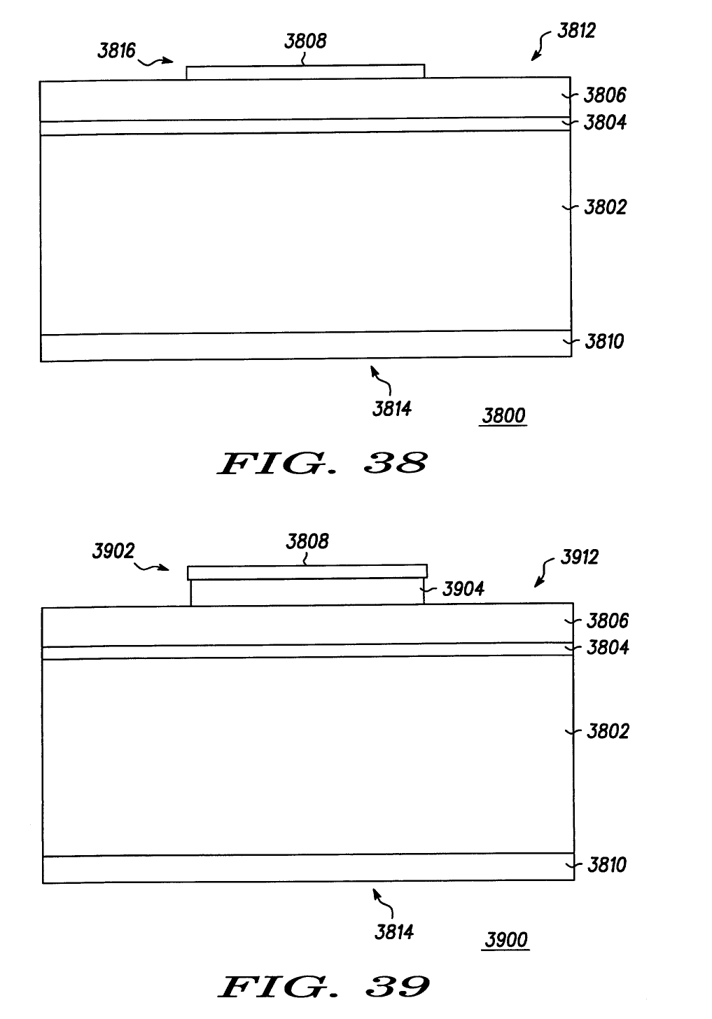

A composite integrated circuit will typically have an electric connection for a power supply and a ground connection. The power and ground connections are in addition to the communications connections that are discussed above. Processing circuitry in a composite integrated circuit may include electrically isolated communications connections and include electrical connections for power and ground. In most known applications, power supply and ground connections are usually well-protected by circuitry to prevent harmful external signals from reaching the composite integrated circuit. A communications ground may be isolated from the ground signal in communications connections that use a ground communications signal. FIGS. 38-65 show several embodiments of semiconductor structures including various transmission media. The embodiments of FIGS. 38-65 are intended to be exemplary only. The structures and methods disclosed therein may be adapted, combined or otherwise modified to suit particular applications.

FIG. 38 shows a cross section of a first embodiment of semiconductor structure 3800 including a microstrip transmission line. The semiconductor structure 3800 in the embodiments of FIGS. 38-65 may be formed in accordance with any of the embodiments described herein, as well as modifications, adaptations and variations thereof. In one particular embodiment, the semiconductor structure 3800 as well as the semiconductor structures illustrated in FIGS. 39-65, includes a monocrystalline silicon substrate 3802 and a buffer layer 3804 formed on the monocrystalline silicon substrate 3802. In one embodiment, the buffer layer 3804 includes an amorphous oxide material overlying the monocrystalline silicon substrate 3802 and a monocrystalline perovskite oxide material overlying the amorphous oxide material. The semiconductor structure 3800 further includes a monocrystalline compound semiconductor material 3806 overlying the monocrystalline perovskite oxide material of the buffer layer 3804. In some embodiments, the monocrystalline compound semiconductor material 3806 is formed from gallium arsenide, gallium aluminum arsenide, indium phosphide or other suitable semiconductor materials as described herein.

As noted, this embodiment is generally illustrated in all the embodiments of FIGS. 38-65. However, any of these embodiments could be altered in accordance with any of the embodiments for manufacturing a semiconductor device described herein. Substitution of materials, rearrangements of layers and omission or addition of layers and materials are all well within the purview of those ordinarily skilled in the art, and may be adopted in order to improve the performance or manufacturability or other features of the illustrated embodiments. However, such changes are well within the scope of the claims below, which define the scope of the invention.

In the embodiment of FIG. 38, the semiconductor structure 3800 further includes a metallization layer 3808 on a first side 3812 of the semiconductor structure and a ground plane metallization 3810 on a second side 3814 of the semiconductor structure 3800. The metallization layer 3808 is patterned according to conventional semiconductor processing to define a microstrip transmission line. The metallization layer 3808 forms a conductor configured to convey radio frequency (RF) energy. The ground plane metallization 3810 forms a ground plane in association with the conductor formed by the metallization layer 3808. The specific geometries of the conductor 3808 may be selected according to manufacturing process and circuit performance requirements. For example, the metallization layer 3808 may have a composition and thickness which defines a predetermined sheet resistance in ohms per square. In order to achieve a required impedance between ends of the microstrip transmission line 3816, the relative width and length of the transmission line, including the metallization layer 3808 may be chosen accordingly by the circuit designer.

FIG. 39 shows a cross section of a second embodiment of a semiconductor structure 3900 including a microstrip transmission line 3902. In the embodiment of FIG. 39, the semiconductor structure 3900 includes a monocrystalline silicon substrate 3802, a buffer layer 3804 and a monocrystalline compound semiconductor material 3806. In addition, a low loss, low dielectric constant dielectric material 3904 is deposited on a portion of the monocrystalline compound semiconductor material 3806 on the first side 3912 of the semiconductor structure 3900. The metallization layer 3808 is formed on the dielectric layer 3904. Examples of a material appropriate for forming the dielectric material 3904 include silicon dioxide, silicon nitride, polyimide, and other materials as well. Examples of suitably low dielectric constant for the dielectric material 3904 are dielectric constants in the range 1.0 to 5.0.

The dielectric material 3904 and the metallization layer 3808 may be formed according to any suitable process, such as by patterning and etching according to conventional semiconductor fabrication processes. Preferably, the two layers 3808, 3904 are self-aligned to improve manufacturability of the semiconductor structure 3900. Preferably, the dielectric material 3904 is deposited on the surface of the monocrystalline compound semiconductor material 3806. However, other techniques of forming a thin film of a suitable dielectric material may be substituted as well. The microstrip transmission line embodiments of FIGS. 38 and 39 make use of the improved semiconductor structures and devices utilizing formation of a compliant substrate, in accordance with the embodiments disclosed herein, to overcome a particular problem. In microstrip transmission lines fabricated on silicon substrates, operation of circuits embodied therein has been limited to frequencies less than approximately 4 GHz. Silicon materials are too lossy for reliable microstrip transmission line fabrication above this frequency. Insertion of the monocrystalline compound semiconductor material 3806 and the buffer layer 3804 isolates the radio frequency energy from the lossy silicon of the monocrystalline silicon substrate 3802. In accordance with an additional embodiment, the monocrystalline compound semiconductor material 3806 may be biased by application of an appropriate bias voltage to further enhance the operation of the microstrip transmission line 3816 of FIG. 38 and microstrip transmission line 3902 of FIG. 39.

FIG. 40 shows a cross section of a first embodiment of a semiconductor structure 4000 including a coplanar waveguide 4002. The semiconductor structure 4000 includes a monocrystalline silicon substrate 3802, buffer layer 3804 and monocrystalline compound semiconductor layer 3806, as described above. In the embodiment of FIG. 40, the monocrystalline silicon substrate 3802 is preferably relatively resistive. This may be achieved by selecting a substrate material which has a relatively high resistivity, or by localized doping to appropriately adjust the resistivity of the silicon substrate in the region of the coplanar waveguide 4002. Suitable values of resistivity for the silicon substrate 3802 in the embodiment of FIG. 40 are 40-50 ohmcm.

The coplanar waveguide 3802 includes a metallization layer 3808 which has been patterned to define a center conductor 4004 and two adjacent outer conductors 4006, 4008. For operation as a waveguide, the outer conductors 4006, 4008 are typically grounded while the center conductor 4004 conveys RF energy.

The geometries of the coplanar waveguide 4002 may be selected according to circuit design requirements and manufacturing requirements. In general, the thickness of the metallization layer 3808 and the minimum spacing of the spaces 4010, 4012 between the semiconductor 4004 and the first outer conductor 4006 and between the center conductor 4004 and the second outer conductor 4008, respectively, are functions of the semiconductor manufacturing process used to fabricate the semiconductor structure 4000. Further, the specified widths and lengths of the center conductor 4004 and the outer conductors 4006, 4008 are specified above a predefined minimum by a circuit designer according to particular circuit design requirements.

In operation, with the outer conductors 4006, 4008 grounded, and a radio frequency or other signal applied to the center conductor 4004, the majority of the electrical energy associated with the coplanar waveguide 4002 is confined to the metallic structure of the metallization layer 3808 and the monocrystalline compound semiconductor layer 3806. In addition, the monocrystalline compound semiconductor layer 3806 may be biased by application of an appropriate bias voltage to further adjust circuit performance.

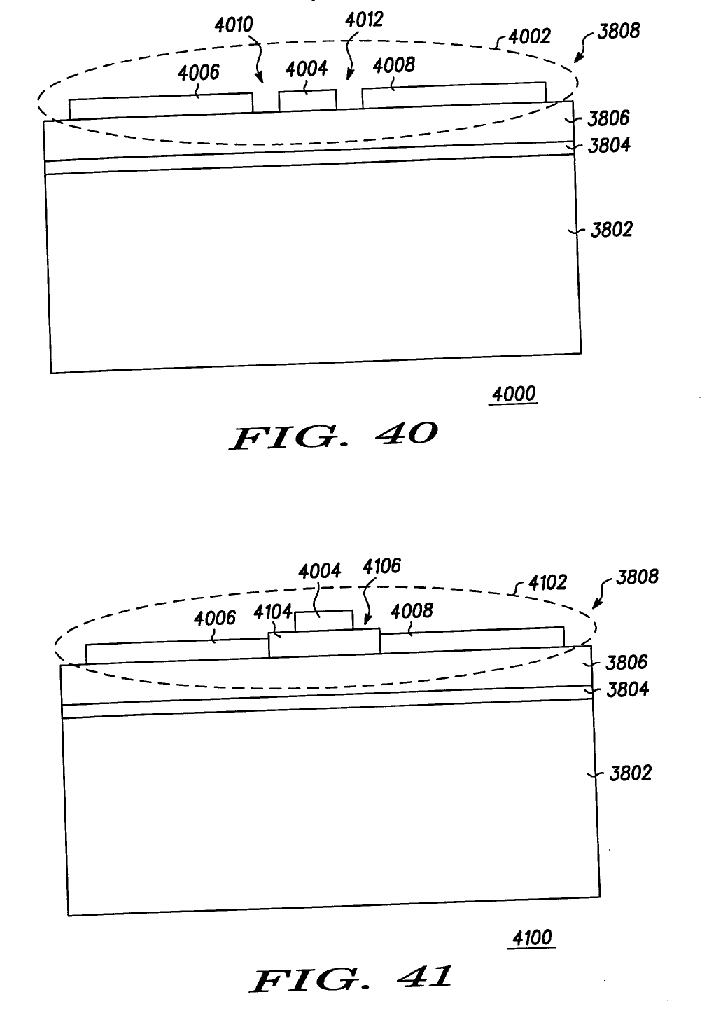

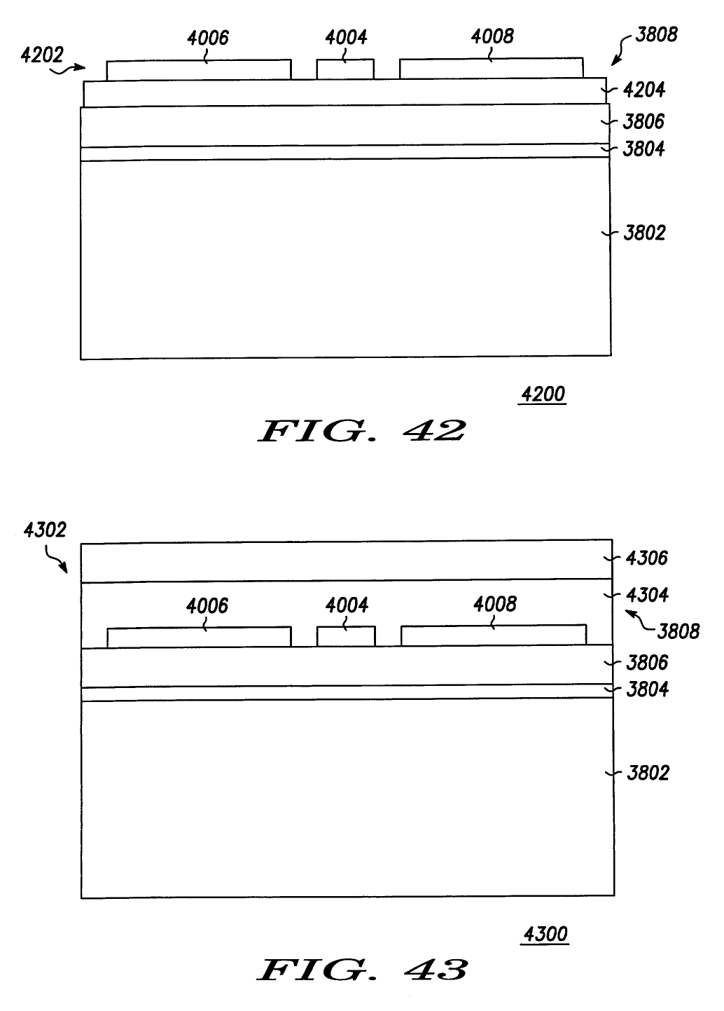

FIG. 41 shows a cross section of a second embodiment of a semiconductor structure 4100 including a coplanar waveguide 4102. The semiconductor structure 4100 includes a monocrystalline silicon substrate 3802, a buffer layer 3804 and a monocrystalline compound semiconductor material 3806. A metallization layer 3808 overlies the monocrystalline compound semiconductor material 3806. The coplanar waveguide 4102 includes a center conductor 4004 and outer conductor 4006, 4008. Further, the coplanar waveguide 4102 includes a dielectric spacer 4104 formed of a relatively low dielectric constant, low-loss dielectric material.

The dielectric spacer 4104 is positioned in the space 4106 between the outer conductors 4006, 4008. The dielectric spacer 4104 is generally coplanar with the outer conductors 4006, 4008. However, the thickness of the dielectric spacer 4104 may be greater than or less than the thickness of the metallization layer 3808 forming the outer conductors 4006, 4008.

The center conductor 4004 is formed on top of the dielectric spacer 4104. In the illustrated embodiment, the center conductor 4004 is formed using the same metallization layer 3808 as is used to form the outer conductors 4006, 4008. In an alternative embodiment, a separate metallization layer may be used to form the center conductor 4004. It may be preferred to use the same metallization layer 3808 for the conductors 4004, 4006, 4008 in order to reduce misalignment between the center conductor 4004 and the outer conductors 4006, 4008 than may arise if separate metallization layers are used. Examples of dielectric materials suitable for forming the dielectric spacer 4104 include polyimide, silicon dioxide and silicon nitride. Examples of a suitable dielectric constant for the low-loss dielectric spacer 4104 are dielectric constants in the range of 1 to 4.

In operation, the dielectric spacer 4104 further serves to block RF energy from the center conductor 4004 passing into the monocrystalline silicon substrate 3802. The bulk of the RF energy leaving the center conductor 4004 is passed to the outer conductors 4006, 4008.

FIG. 42 shows a cross section of a third embodiment of a semicoductor structure 4200 including a coplanar waveguide 4202. The semiconductor structure 4200 includes a monocrystalline silicon substrate 3802, a buffer layer 3804 and a monocrystalline compound semiconductor layer 3806, as described above. In the embodiment of FIG. 42, a relatively low dielectric constant, low-loss dielectric layer 4202 is positioned beneath both the center conductor 4004 and outer, ground conductors 4006, 4008 of the coplanar waveguide 4202. The low-loss dielectric material 4204, in combination with the ground conductors 4006, 4008 and the compound semiconductor layer 3806, serves to isolate or shield RF energy in the center conductor 4004 from the lossy silicon substrate 3802.

Relative geometries for the center conductor 4004 and outer conductors 4006, 4008 may be chosen according to particular requirements of the circuits and manufacturing performance. Other features, such as the overlap required between the dielectric layer 4204 and the outer edges of the outer conductors 4006, 4008 may be set by semiconductor processing requirements and the ability and need to minimize misalignment between the metallization layer 3808 and the dielectric material 4204. The dielectric material 4204 may be patterned and selectively removed from the surface of the semiconductor structure 4200 using conventional semiconductor processing techniques. Such patterning and removal may be done in order to allow fabrication of active and passive compound semiconductor devices in the compound semiconductor material 3806. Suitable values for the dielectric constant for the dielectric material 4202 are dielectric constants in the range 1 to 4. Suitable materials for the dielectric material 4202 are polyimide, silicon dioxide and silicon nitride.

FIG. 43 shows a cross section of a fourth embodiment of semiconductor structure 4300 including a coplanar waveguide 4302. The semiconductor structure includes a monocrystalline silicon substrate 3802, a buffer layer 3804 and a monocrystalline compound semiconductor material 3806. A metallization layer 3808 is formed on the monocrystalline compound semiconductor layer 3806 The metallization layer 3808 is patterned to define a center conductor 4004 and outer conductors 4006, 4008.

In accordance with the embodiment of FIG. 43, a relatively high dielectric constant, low-loss dielectric material 4304 overlies the metallization layer 3808 and the monocrystalline compound semiconductor material 3806. In addition, in one embodiment, an optional top ground plane metallization layer 4306 is formed on the low-loss dielectric layer 4304. The top ground plane metallization layer 4306 may be omitted in some embodiments.

Suitable dielectric materials 4304 having a relatively high dielectric constant and being relatively low-loss are Strontium Titanate, Barium Strontium Titanate, Strontium Zirconate, Barium Zirconate, or similar materials. An appropriate dielectric constant for the material 4304 is in the range of 20 to 80.

In operation, the high dielectric constant material 4304 and the compound semiconductor material 3806 serve to confine the RF electrical energy to the center conductor 4004 and the outer conductors 4006, 4008. Little energy extends into the lossy silicon substrate 3802. Further, little energy extends into the free space or other material above the semiconductor structure 4300 because the energy is contained by the relatively high dielectric constant dielectric material 4304.

FIG. 44 shows a cross section of a fifth embodiment of the semiconductor structure 4400 including a coplanar waveguide 4402. The semiconductor structure 4400, like other embodiments described herein, includes a monocrystalline silicon substrate 3802, a buffer layer 3804 and a monocrystalline compound semiconductor material 3806. In the illustrated embodiment, the silicon substrate 3802 has a relatively high conductivity. Suitable conductivity for the silicon substrate 3802 is in the range of 50 to 100 S/cm.

A metallization layer 3808 is formed on the compound semiconductor material 3806. The metallization layer 3808 is patterned to define a center conductor 4004 and outer conductors 4006, 4008. A space 4404 is left after patterning of the metallization layer 3808 between the center conductor 4004 and the outer conductor 4006. Similarly, a space 4406 is left between the center conductor 4004 and the outer conductor 4008 after patterning and etching of the metallization layer 3808.

In the illustrated embodiment, a portion of the monocrystalline compound semiconductor material 3806 is removed in the spaces 4404, 4406 between the center conductor 4004 and the outer conductors 4006, 4008, respectively. The compound semiconductor material 3806 may be removed by etching the compound semiconductor material, or by any other suitable method. In an alternative embodiment, the compound semiconductor material 3806 may be grown locally, as shown, leaving bare the spaces 4404, 4406. Any suitable method for defining the spaces 4404, 4406 between the portions of the metallization layer 3808 may be used.

The spaces 4404, 4406 in the embodiment of FIG. 44 are filled with dielectric bricks 4408, 4410. The dielectric bricks 4408, 4410 may be deposited in the spaces 4404, 4406, or may be grown by selective epitaxy over a similar process. Any suitable method for filling the trenches or spaces 4404, 4406 may be used. Materials suitable for use as the dielectric bricks 4408, 4410 include Strontium Titanate, Barium Strontium Titanate, Strontium Zirconate, Barium Zirconate, and other suitable materials. The dielectric constant for the relatively high dielectric constant material used for the dielectric bricks 4408, 4410 preferably is a dielectric constant in the range of 20 to 80.

In operation, the dielectric bricks, along with the monocrystalline compound semiconductor material 3806, serve to isolate the silicon substrate 3802 from the radio frequency energy being conducted in the center conductor 4004. The coplanar waveguide 4402 confines substantially all the RF energy in the center conductor 4004 and the outer conductors 4006, 4008.

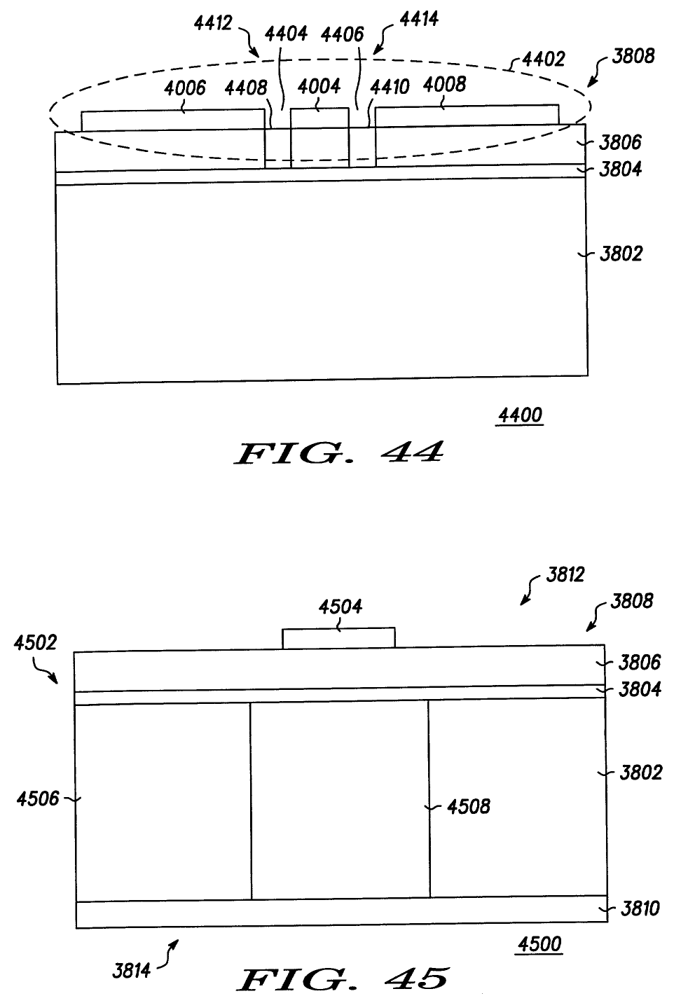

FIG. 45 shows a cross section of a semiconductor structure 4500 including a suspended substrate microstrip line 4502. The semiconductor structure 4500 includes a monocrystalline silicon substrate 3802, a buffer layer 3804 and a monocrystalline compound semiconductor layer 3806. A metallization layer 3808 is formed on the monocrystalline compound semiconductor layer 3806. The metallization layer 3808 is patterned to define a microstrip conductor 4504 on a first side 3812 of the semiconductor structure 4500. A ground plane metallization is formed on a second side 3814 of the semiconductor structure 4500.

In the illustrated embodiment of FIG. 45, a portion of the monocrystalline silicon substrate 3802 is removed to define a trench or aperture 4506. The trench or aperture is then filled with a relatively low dielectric constant, low-loss dielectric material 4508. Suitable materials for the dielectric material 4508 include silicon dioxide and polyimide. Suitable dielectric constants for the dielectric material 4508 are dielectric constants in the range 1-5. Other materials or materials having other dielectric constants may be substituted.

In conventional microstrip applications, the adjacent dielectric material is typically air. Preferably the dielectric material 4508 has properties, including a dielectric constant, comparable to those of air. Also preferably, the dielectric material 4508 is less lossy than silicon, such as the silicon substrate 3802. In the illustrated embodiment, with the dielectric material 4508 adjacent to the microstrip line 4504, radio frequency energy passing from the microstrip conductor 4504 to the ground plane metallization 3810 would generally pass through the low-loss dielectric material 4508, rather than through the lossy silicon substrate 3802. This reduces the loss seen by the microstrip transmission line 4502 .

FIG. 46 shows a cross section of a semiconductor structure 4600 including an inverted suspended-substrate microstrip line 4602. The semiconductor structure 4600 includes a monocrystalline silicon substrate 3802, a buffer layer 3804 and a monocrystalline compound semiconductor layer 3806 on a first side 3812 of the semiconductor structure 4600. On a second side 3814, a ground plane metallization 3810 is formed.

The semiconductor structure 4600 further includes a microstrip conductor 4604 and a relatively low dielectric constant, low-loss dielectric material 4606. The dielectric material 4606 fills a trench or other opening 4608 within the silicon substrate 3802. The dielectric material 4606 preferably extends substantially all the way through the silicon substrate 3802, from the ground plane metallization 3810 to the buffer layer 3804. The microstrip conductor 4604 may be formed in a any suitable manner in conjunction with the dielectric layer 3806. In one example, a trench would be defined in the top surface of the dielectric layer 3806 after the opening 4608 is filled with the dielectric layer 3806. The trench and other portions of the top surface of the semiconductor structure 4600 would then be subsequently filled with metal. The metal would then be etched or polished away from other portions of the top surface of the semiconductor structure, leaving the trench filled with the metallization, forming the microstrip conductor 4604. Other suitable methods may be substituted as well. The buffer layer 3804 is then formed directly over the silicon substrate 3802, the dielectric material 4606 and the metallization of the microstrip conductor 4604. The monocrystalline compound semiconductor material 3806 is subsequently formed on the buffer layer 3804, in accordance with the embodiments disclosed herein.

The inverted suspended substrate microstrip line 4602 of FIG. 46 operates to contain RF energy within the low-loss cavity defined by the buffer layer 3804, the silicon substrate 3802 and the ground plane metallization 3810. As signals pass along the microstrip transmission line, radio frequency energy passes from the microstrip conductor 4604 through the dielectric material 4606. Little radio frequency energy is lost in the lossy silicon substrate 4802.

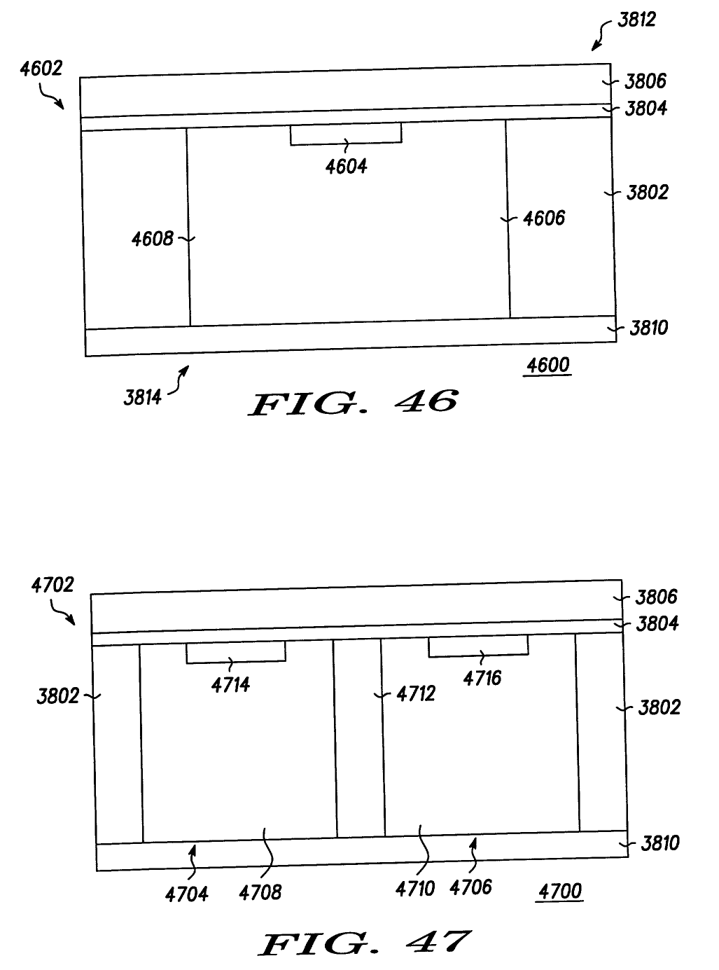

FIG. 47 shows a cross section of a semiconductor structure 4700 including a parallel inverted suspended-substrate microstrip line 4702. The semiconductor structure 4700 is formed using a monocrystalline silicon substrate 3802, a buffer layer 3804 and a monocrystalline compound semiconductor material 3806. A ground plane metallization 3810 is formed on a back side of the semiconductor structure 4700.

In the embodiment of FIG. 47, parallel cavities 4704, 4706 are defined in the monocrystalline silicon substrate 3802. The cavities 4704, 4706 may be formed in any suitable manner. For example, trenches may be etched in the silicon substrate 3802 to define the cavities, which are subsequently filled with a relatively low dielectric constant, low-loss dielectric material 4708, 4710. In the illustrated embodiment, the dielectric material in each of the cavities 4704, 4706 is the same dielectric material. However, in particular applications, different dielectric materials may be used. The cavities 4704, 4706 are separated by a shielding wall 4712 of relatively conductive silicon. The conductivity of the silicon forming the silicon wall 4712 may be in the range 5-10 ohm-cm. The silicon of the shielding 4712 may have a relatively high bulk conductivity or may be doped to have a relatively high conductivity in a localized region.

Microstrip conductors 4714, 4716 are contained within each of the cavities 4704, 4706. The microstrip conductors 4714, 4716 may be formed in any suitable manner, such as the fabrication techniques described above in connection with FIG. 46. The parallel inverted suspended-substrate microstrip lines 4702 of FIG. 47 may be used for conveying data or other information. While two parallel lines are shown in FIG. 47, any suitable number may be formed in alternative embodiments. The shielding wall 4712 operates to limit crosstalk or electrical coupling between the microstrip conductors 4714, 4716 of the parallel cavities 4704, 4706. Thus, the cavities look like isolated cavities, each cavity generally electrically isolated from the adjacent cavity. In another embodiment the shielding wall 4712 may be omitted thus forming parallel coupled lines.

FIG. 48 shows a cross section of a first embodiment of a semiconductor structure 4800 including a strip line 4802. The semiconductor structure 4800 includes a monocrystalline silicon substrate 3802, a buffer layer 3804 and a monocrystalline compound semiconductor layer 3806. The silicon of the monocrystalline silicon substrate 3802 in the vicinity of the strip line 4802 is preferably relatively high conductivity silicon. In one example, the conductivity of the silicon may be 50-100 S/cm. Other conductivity levels may be used. The high conductivity silicon may be bulk in the silicon substrate 3802 or the region near the strip line conductor 4802 may be doped or implanted to improve the conductivity of the silicon.

A strip line conductor 4804 is formed on the monocrystalline compound semiconductor material 3806. The strip line conductor 4804 may be formed by depositing a metallization layer and patterning the strip line conductor to desired width and length.

A dielectric material 4806 is formed on the monocrystalline compound semiconductor material 3806 and on the metallization of the strip line conductor 4804. The dielectric material 4806 preferably has a dielectric constant and loss tangent similar to that of compound semiconductor materials. Some examples include Aluminum Antimonide, Aluminum Oxide. Alternatively, the compound semiconductor material 4806 may be the same compound semiconductor material used to form the monocrystalline compound semiconductor layer 3806. A ground plane 4808 is formed on the compound semiconductor dielectric material 4806.

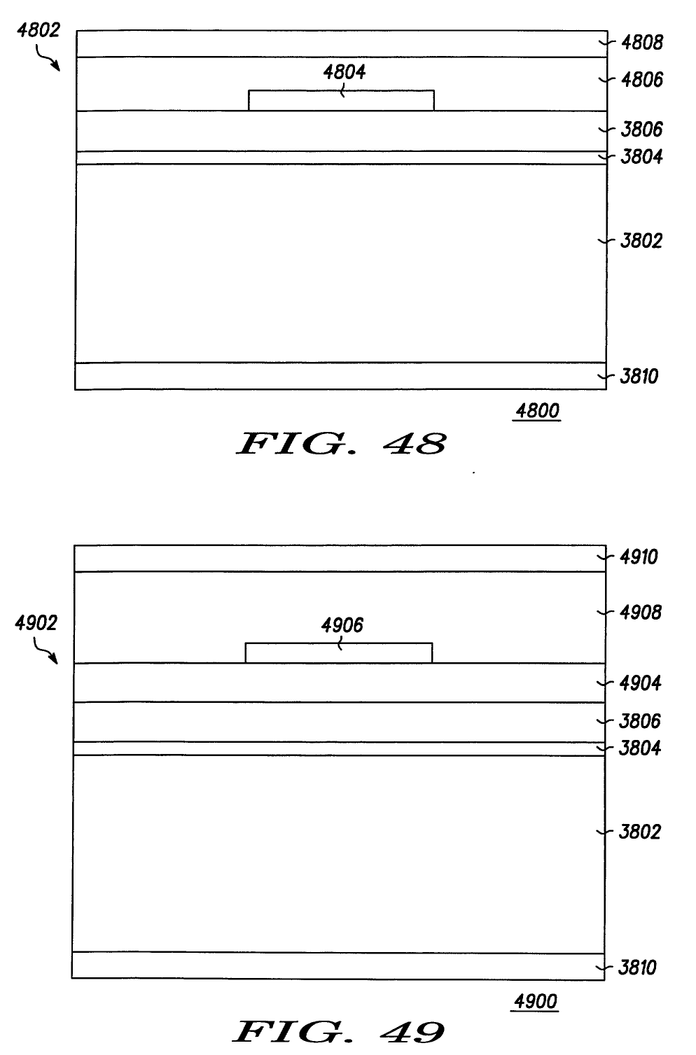

FIG. 49 shows a cross section of a second embodiment of a semiconductor structure 4900 including a strip line 4902. The semiconductor structure 4900 includes a monocrystalline silicon substrate 3802, a buffer layer 3804 and monocrystalline compound semiconductor layer 3806. A ground plane metallization is formed on a back side 3810 of the semiconductor structure 4900. The silicon of the silicon substrate 3802, at least in the vicinity of the strip line 4902, is relatively high conductivity. In one example, the silicon of the substrate 3802 may be have a conductivity in the range 2-4 ohm-cm.

In the embodiments of FIG. 49, a dielectric material 4904 is formed on the monocrystalline compound semiconductor material 3806. The strip line conductor 4906 of the strip line 4902 is formed by depositing a metallization layer on the first dielectric layer 4904 and patterning the metallization layer to appropriate dimensions for the strip line conductor. A second dielectric material 4908 then overlies the first dielectric layer 4904 and the metallization of the strip line conductor 4906. In the illustrated embodiment, a ground plane 4910 is formed on the dielectric layer 4908. The dielectric layers 4904, 4908 may be any suitable material. In one example, the layers 4904, 4908 are formed using the same monocrystalline compound semiconductor material as is used for the layer 3806. In other embodiment, other materials, such as other Group III-V materials or other dielectric materials processing specific electrical and mechanical properties may be used.

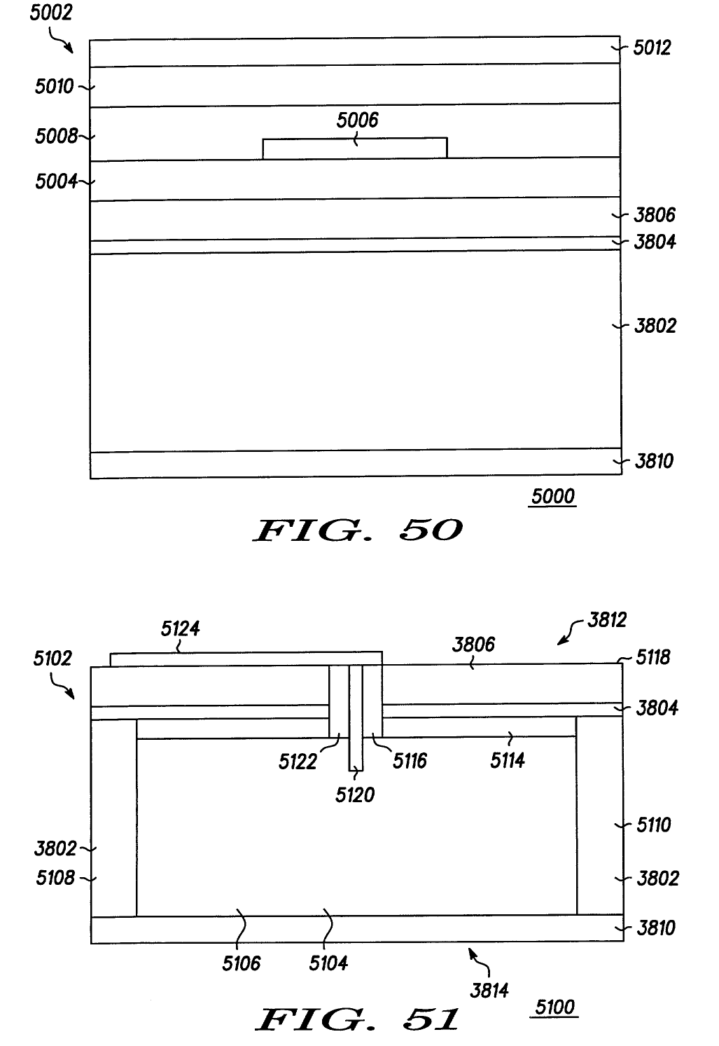

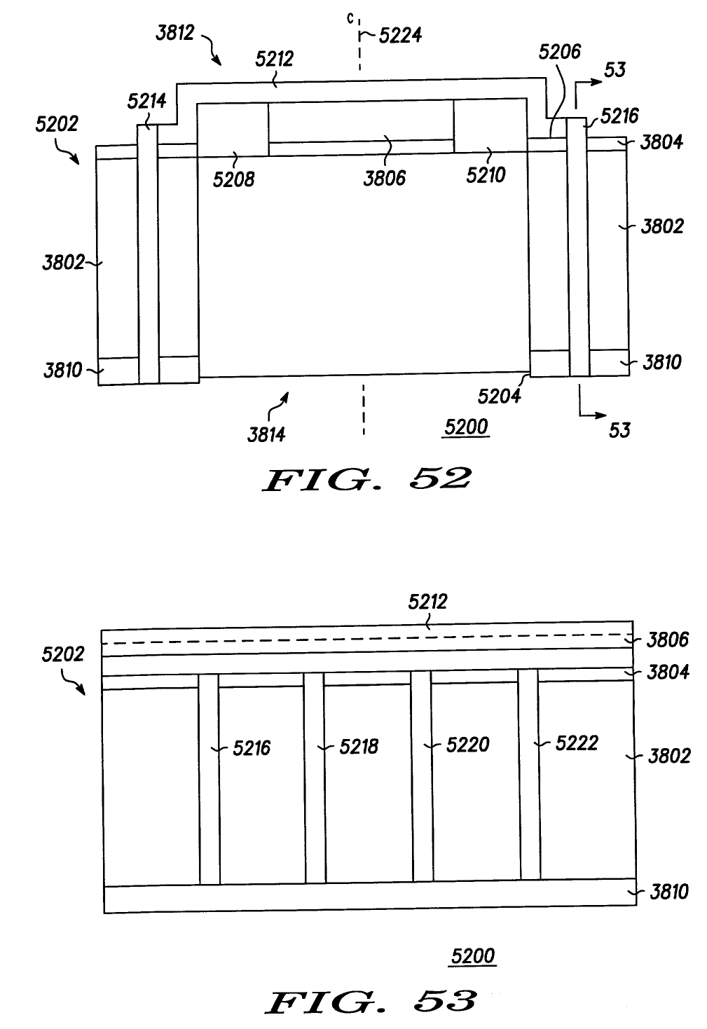

FIG. 50 shows a cross-section of a third embodiment of a semiconductor structure 5000 including a strip line 5002. This semiconductor structure 5000 includes a monocrystalline silicon substrate 3802, a buffer layer 3804 and a monocrystalline compound semiconductor layer 3806. The silicon of the silicon substrate 3802 is preferably relatively high conductivity. A ground plane metallization 3810 is formed on the back side of the semiconductor structure 5000.

A relatively low dielectric constant, low-loss dielectric material 5004 is formed on the monocrystalline compound semiconductor material 3806. A metallization layer is formed on the top surface of the dielectric material 5004 and patterned to define a stripline conduct 5006. The stripline conductor 5006 may have any appropriate dimensions, including length and width, necessary for operation in a circuit. A relatively low dielectric constant, low-loss dielectric material 5008 overlies the dielectric material 5004 and the stripline conductor 5006. Suitable dielectric materials for the dielectric layers 5004, 5008 include polyimide, silicon dioxide and silicon nitride. Preferably, the dielectric layers 5004 and 5008 are made of materials having dielectric constants in the range of 1 to 4 and also should be the same material.

A compound semiconductor dielectric material 5010 overlies the dielectric layer 5008. In one embodiment, the dielectric layer 5010 may be formed of the same compound semiconductor material as the monocrystalline compound semiconductor layer 3806. Preferably, the compound semiconductor dielectric 5010 has a dielectric constant in the range of 5 to 12. The dielectric 5010 is preferably the same as layer 3806. A different material having very similar electrical characteristics (Dielectric constant and Loss tangent-Dk and Lt) could be used. In the embodiment of FIG. 50, the structure of the dielectric layers 5004, 5008, 5010 has improved symmetry relative to the embodiments of FIGS. 48 and 49. The same type if dielectric material is formed on both sides, above and below in FIG. 50, of the strip line conductor 5006. This can improve the performance of a strip line transmission line operating in a circuit.

FIG. 51 shows a cross-section of a semiconductor structure 5100 including a dielectric-filled waveguide 5102. The semiconductor structure 5100 includes a monocrystalline silicon substrate 3802, a buffer layer 3804 and a monocrystalline compound semiconductor material layer 3806. A ground plane metallization 3810 is formed on a back side of the semiconductor structure 5100.

A portion of the silicon substrate 3802 has been removed and filled to define a rectangular waveguide 5104. The waveguide 5104 in the illustrated embodiment is filled with a relatively low dielectric constant, low-loss dielectric material 5106. The rectangular waveguide 5104 may be formed in any suitable manner, for example by etching the silicon of the substrate 3802. The silicon substrate 3802 defines the right and left walls 5108, 5110 of the waveguide 5104. The silicon forming the right and left walls 5108, 5110 is preferably relatively high conductivity silicon. This may be achieved by using high conductivity bulk silicon or by localized doping of the silicon in the region of the waveguide 5102.

On the top or front side 3812 of the semiconductor structure 5100, a metallization layer 5114 is formed. The metallization layer 5114 forms a top layer metallization for the dielectric-filled waveguide 5102. Also on the front side 3812 of the semiconductor structure 5100, an aperture 5116 has been defined to provide electrical access to the dielectric-filled waveguide 5102. Within the aperture 5116, a metallic electric plane (E-plane) probe 5120 extends into the dielectric material 5106. In one embodiment, the probe 5120 is formed by defining and filling a via through the monocrystalline compound semiconductor material 3806, the buffer layer 3804 and a portion of the dielectric material 5106. The remaining portion of the aperture 5116 is filled with an insulating dielectric material 5122. In a typical application, as illustrated in FIG. 51, a metallization layer 5124 is patterned to define a transmission line connecting with other circuitry integrated with the semiconductor structure 5100. The dielectric-filled waveguide 5102 of FIG. 51 operates similar to an antenna in a conductive tube. The probe 5120 operates like an antenna, radiating electromagnetic energy in the waveguide 5102. The waveguide, with conductive walls formed by the metallization 5114, conductive silicon walls 5108, 5110 and bottom metallization 3810, forms a relatively conductive tube for containing energy emitted by the antenna or probe 5120.

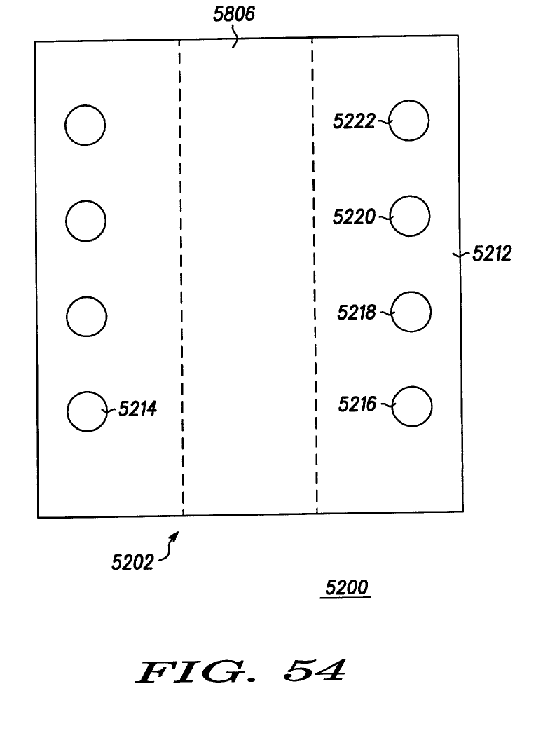

FIG. 52 shows a cross-section of the semiconductor structure 5200 including a trapped image line 5202. FIG. 53 shows a cross-section of the semiconductor structure 5200 taken along line 53-53 in FIG. 52. FIG. 54 shows a top view of the semiconductor structure 5200 including the trapped image line 5202 of FIG. 52 and FIG. 53. Referring to FIGS. 52, FIG. 53, 54, the semiconductor structure 5200 includes a monocrystalline silicon substrate 3802, a buffer layer 3804 and a monocrystalline compound semiconductor layer 3806. The semiconductor structure including these materials may be formed in accordance with any of the embodiments described herein. A portion of the silicon substrate 3802 has been removed to define a void or trench 5204. The trench 5204 preferably extends completely through the silicon substrate 3802. The trench 5204 is subsequently filled with a relatively low dielectric constant low-loss dielectric material 5206. Suitable materials for the dielectric material 5206 include silicon dioxide and silicon nitride. Suitable dielectric constants of the dielectric material 5206 include dielectric constants in the range 1-5.

The silicon of the silicon substrate 3802 on either side of the dielectric material 5204 is preferably relatively high conductivity silicon. The high conductivity may be achieved by employing a relatively high conductivity silicon substrate 3802 or by localized doping or implantation of the silicon substrate 3802 in the region surrounding the trapped image line 5202. Appropriate values for the conductivity of the silicon forming the silicon substrate in the vicinity of the trapped image line 5202 are in the range of 50-100 S/cm.

The buffer layer 3804 is formed on the monocrystalline silicon substrate 3802 and on the dielectric material 5206. Portions of the buffer layer 3804 are removed or omitted and dielectric spacers 5208, 5210 are formed on the dielectric material 5206. The dielectric spacers 5208 from 5210 are preferably formed of a relatively low dielectric constant, low-loss dielectric material such as silicon dioxide or silicon nitride. The dielectric spacers may be the same dielectric material used to form the dielectric material 5206. A top metallization layer 5212 is formed on the dielectric spacers 5208, 5210 and on the monocrystalline compound semiconductor material 3806. The top metallization layer 5212 may be patterned to define the appropriate width and length for the trapped image line 5202.

Vias 5214, 5216 are formed to connect the top layer metallization 5212 and the ground plane metallization 3810. The vias extend through the buffer layer 3804, the monocrystalline silicon substrate 3802 and are in electrical contact with the metallization 3810 on the second side 3814 of the semiconductor structure 5200. As shown in FIG. 52, the via 5214 is on a first side of the void 5204 filled with dielectric material 5206 and the via 5216 is on a second side of the void 5204. As shown in FIGS. 53 and 54, the via 5216 is one via of a series of vias 5216, 5218, 5220, 5222 aligned along the trapped image line 5202. In the trapped image line 5202, the via 5204 is one via of a set of vias similar to the vias 5216, 5218, 5220, 5222, aligned on the first side of the trapped image line 5202. Preferably, the via arrangement is generally symmetrical about a center line 5224. In the illustrated embodiment, the trapped image line 5202 includes four pairs of vias such as via pair 5214, 5216. In other embodiments, the number of vias may vary depending on the length of the trapped image line and the spacing chosen for the vias. Also, in other embodiments, the vias on opposite sides of the trapped image line may not be positioned as via pairs as shown in FIGS. 52, 53, 54, but instead may be staggered or otherwise arranged on either side of the trapped image line 5202.

The trapped image line 5202 thus forms a dielectric waveguide within an electrically conductive trough. The boundaries of the trough are defined by the top layer metallization 5212, and the highly conductive silicon regions 3802 in conjunction with the vias 5214 and 5216. The vias, such as vias 5214, 5216 provide increased metallic shielding and serve to better approximate a conductive wall, depending on spacing, frequency of operation and other factors.

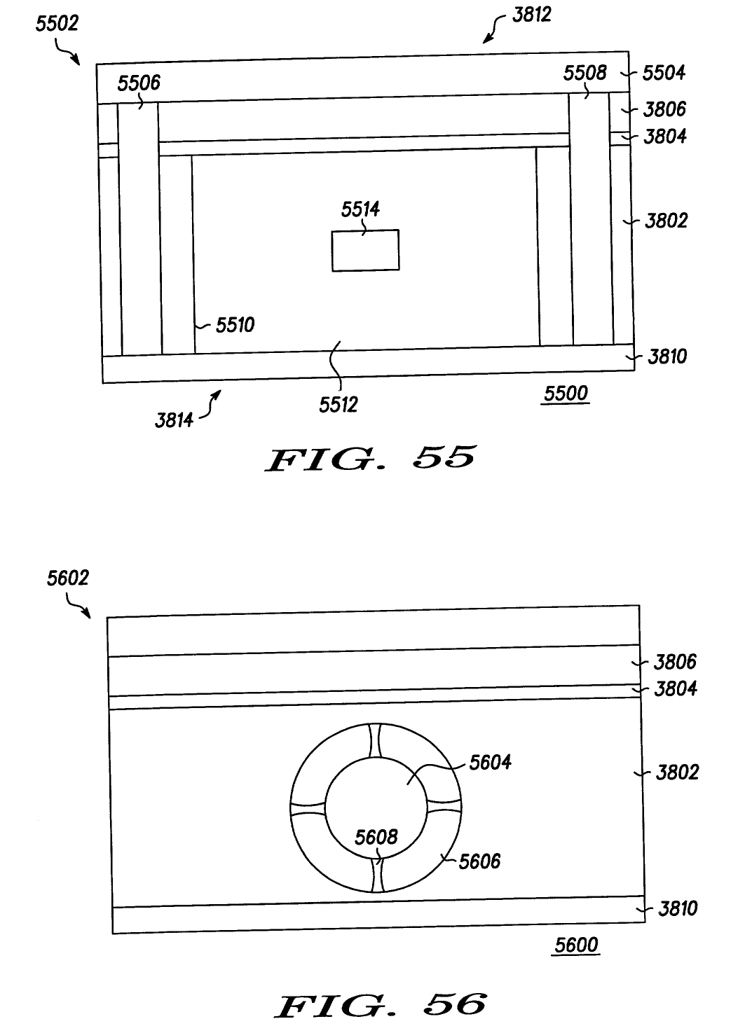

FIG. 55 shows a cross-section of a semiconductor structure 5500 including a rectangular coaxial waveguide 5502. The semiconductor structure 5500 includes a monocrystalline silicon substrate 3802, a buffer layer 3804 and a monocrystalline compound semiconductor layer 3806. The silicon substrate 3802 is preferably relatively high conductivity bulk silicon. Suitable conductivities for the silicon of the embodiment of FIG. 55 are in the range of 50-100 S/cm. Other conductivities may be used or the silicon may be locally doped to enhance its conductivity.

A top metallization 5504 is formed on a first side 3812 of the semiconductor structure 5500. A bottom metallization 3810 is formed on a second side 3814 of the semiconductor structure 5500. Vias are formed to electrically connect the top metallization 5504 and the bottom metallization 3810. A first via 5506 and a second via 5508 are formed, penetrating the monocrystalline compound semiconductor layer 3806, the buffer layer 3804 and the monocrystalline silicon substrate 3802. In some embodiments, the vias 5506, 5508 may be two vias of two lines of vias, aligned along the length of the rectangular coaxial waveguide 5502. The positioning of the vias in such an embodiment is similar to the embodiment of a semiconductor structure including a trapped image line of FIG. 53. Alternatively, other numbers of vias may be included in the rectangular coaxial waveguide 5502, such as vias placed only at the ends of the waveguide 5502. Generally, the via spacing and placement depends on frequency of operation, manufacturing capabilities and other factors.

A central portion 5510 of the silicon substrate 3802 has been removed and filled with a dielectric material 5512. Formed generally in the center of the dielectric material 5512 is a center conductor 5514. The center conductor 5514 is preferably metal and extends the length of the rectangular coaxial waveguide. Ends of the waveguide 5502 may include vias for electrically contacting the center conductor 5514 and coupling the center conductor 5514 to other signal conductors of the semiconductor structure 5500. The center conductor 5514 and dielectric material 5512 may be formed in any suitable manner. For example, after removing the silicon from the central region 5510 of the silicon substrate 3802, the central region 5510 may be filled partly with the dielectric material 5512. A central portion may then be etched or otherwise removed of the dielectric material 5512 and subsequently filled with metallization to form the center conductor 5514. The remainder of the center portion 5510 may then be filled with dielectric material 5512.

Thus, the rectangular coaxial waveguide 5502 provides operation similar to a coaxial cable. The top metallization 5504, bottom metallization 3810 and vias 5506, 5508 serve as an outer shield, shielding the center conductor 5514, and containing radio-frequency energy within the waveguide 5502.

FIG. 56 shows a cross-section of a semiconductor structure 5600 including a cylindrical coaxial waveguide 5602. The semiconductor structure 5500 includes a monocrystalline silicon substrate 3802, a buffer layer 3804 and a monocrystalline compound semiconductor layer 3806. The silicon of the silicon substrate 3802 is preferably relatively high conductivity silicon, forming a high conductivity silicon outer conductor. For example, the conductivity of the silicon substrate 3802 may be in the range 50-100 S/cm.

The semiconductor structure 5600 further includes a silicon center conductor 5604 spaced from the silicon substrate 3802 by a spacer region 5606. The center conductor 5604 is preferably relatively high conductivity silicon, with a conductivity, for example, in the range 50-100 S/cm. The center conductor 5604 is spaced from the silicon substrate 3802 by dielectric stand-offs 5608. The stand-offs 5608 are preferably an insulating dielectric to electrically insulate the center conductor 5604 from the silicon substrate 3802 forming the outer conductor. As shown in FIG. 56, the center conductor 5604 and the interior of the spacer region 5606 are generally cylindrical in shape, having a circular or elliptical shape in cross-section. However, other shapes may be used as well. The spacer-region 5606 may be formed by micro machining or by etching or by other suitable methods now known or later developed. Further, the spacer region 5606 may be filled with air or another dielectric material.

Thus, the coaxial waveguide 5602 operates similarly to a coaxial cable by surrounding a center conductor with a conductive shield region, the conductive silicon of the silicon substrate 3802. This serves to shield the center conductor from cross talk and external interference as well as to contain the radio frequency energy of the center conductor 5604 within the waveguide 5602.

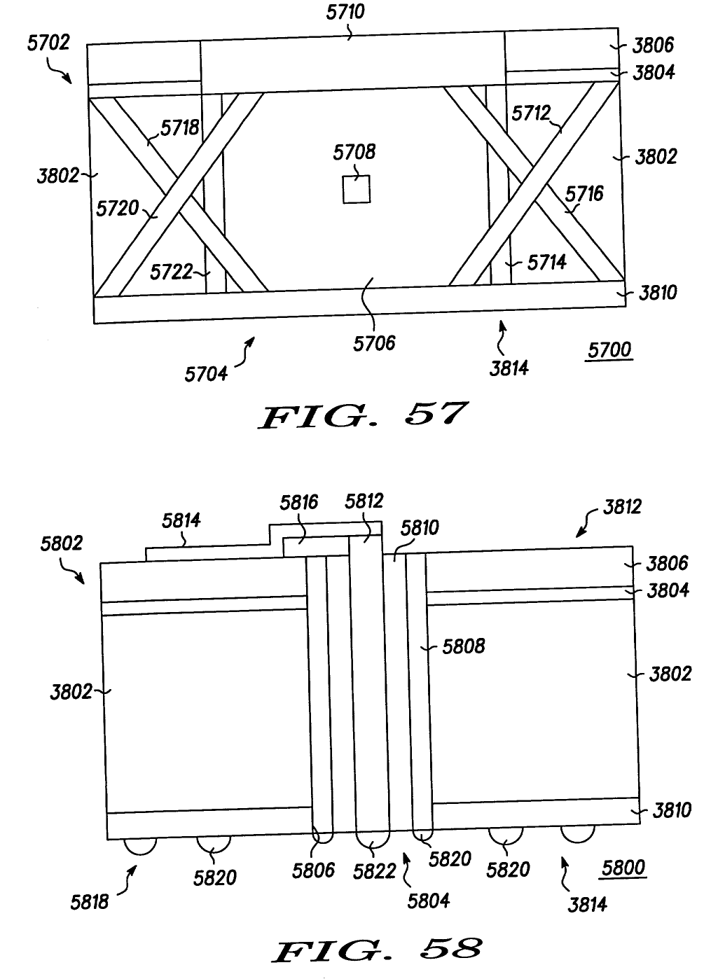

FIG. 57 shows a cross-section of a semiconductor structure 5702 including a quasi-cylindrical coaxial waveguide 5702. The semiconductor structure 5700 is formed using a monocrystalline silicon substrate 3802, a buffer layer 3804 and a monocrystalline compound semiconductor layer 3806. A ground plane metallization 3810 is formed on a back side 3814 of the semiconductor structure 5700.

A center portion 5704 of the semiconductor structure 5700 has had the silicon substrate 3802 removed and replaced with a dielectric material 5706. Any suitable dielectric material, as described herein, may be used. A center conductor 5708, made of metal or other suitable conductive material is positioned generally in the center of the dielectric material 5706.

To simulate the shielding effects of a coaxial cable, a top layer metallization 5710 and vias 5712, 5714, 5716, 5718, 5720, 5722 are formed to generally surround the center conductor 5708. The vias 5714, 5722 are vertical vias extending between the top layer metallization 5710 and the bottom layer metal 3810. The vias 5712, 5716, 5718 and 5720 are diagonal vias extending between the bottom layer metallization 3810 and the buffer layer 3804. In alternative embodiments, the top layer metallization 5710 may be extended laterally to make electrical contact with the ends of the diagonal vias. It is to be noted that the vias do not all lie in the same plane in the illustrated embodiment. In this embodiment, the vertical vias 5714, 5722 lie in a first plane most distant from the viewer, the diagonal vias 5716, 5718 lie in the second plane, closer to the viewer than the vertical vias 5714, 5722, and the diagonal vias 5712, 5720 lie in a plane closest to the viewer. Alternative embodiments are possible, for example, with each via residing in its own plane.

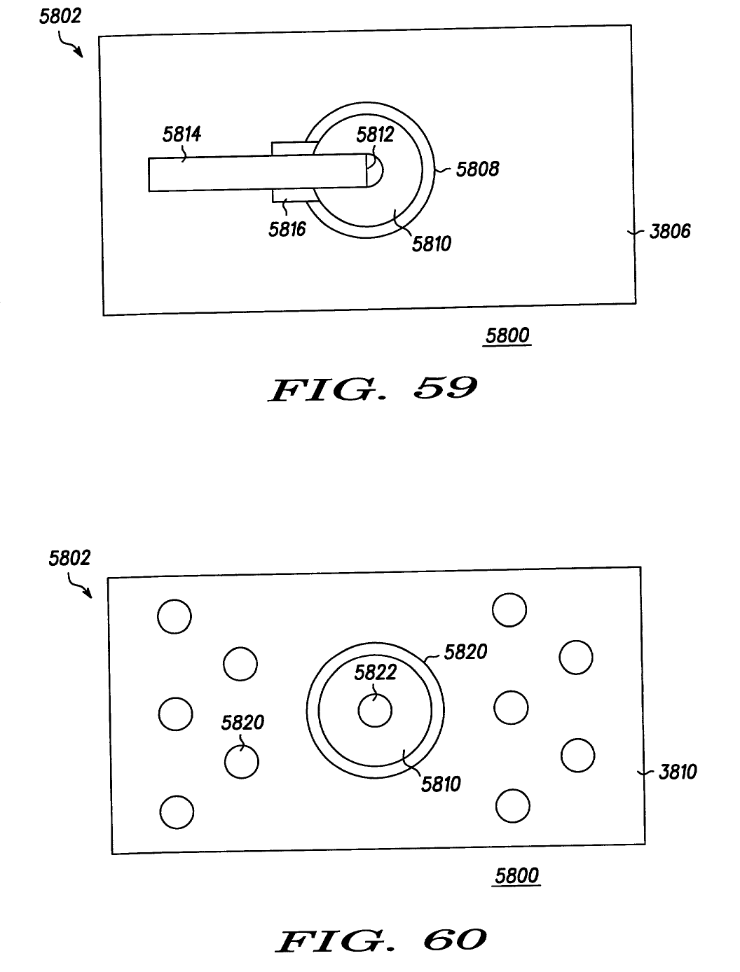

FIG. 58 shows a cross-section of a semiconductor structure 5800 including a vertical coaxial waveguide 5802. FIG. 59 shows a top view of the semiconductor structure 5800 of FIG. 58. FIG. 60 shows a bottom view of the semiconductor structure 5800 of FIG. 58. The vertical coaxial waveguide 5802 of FIGS. 58, 59, 60 forms a radio frequency feed through from one side of the semiconductor structure 5800 to the other side.

The semiconductor structure 5800 includes a monocrystalline silicon substrate 3802, a buffer layer 3804 and a monocrystalline semiconductor material layer 3806. On the first side of the semiconductor structure 5800, a ground plane metallization 3810 is formed on a second side 3814 of the semiconductor structure 5800.

To form the vertical coaxial waveguide, a central portion 5804 of the silicon substrate 3802 is removed, for example, by etching or by other means. Preferably, the removed central portion 5804 is generally cylindrical in shape, having a circular or elliptical cross-section as shown in FIG. 59 and FIG. 60. Other cross-sections may be substituted. An inner surface 5806 of the removed central portion 5804 is deposited with metallization to form an outer conductor 5808. This metallization may be formed by any suitable means, including filling the entire central portion 5804 with metal and etching or otherwise removing a central portion of the metal to define a central void. The resulting shape of the outer conductor 5808 is that of a hollow cylinder. A central portion of the hollow cylinder of the outer conductor 5808 is filled with a dielectric material 5810. The center of the central portion is filled with a center conductor 5812. The dielectric material 5810 is preferably insulating so as to electrically insulate the center conductor 5812 from the outer conductor 5808. The dielectric material may be etched to define a void which is subsequently filled with metal or other conductive material to form the center conductor 5812. To provide an electrical contact between the center conductor 5812 and metal interconnect 5814, a dielectric spacer 5816 is formed on the top of the semiconductor structure 5800. The dielectric spacer 5816 isolates the metal interconnect 5814 from the outer conductor 5808.

In the embodiment of FIGS. 58, 59, 60, solder bumps 5818 are formed on the bottom metallization layer 3810. The solder bumps 5818 include ground solder bumps 5820 formed directly on the ground metallization layer 3810 and on the end of the outer conductor 5808, and a center conductor solder bump 5822 formed on the end of the center conductor 5812. The solder bumps 5818 allow direct electrical connection to the back side 3814 of the semiconductor structure 5800, for example and flip-chip type applications.

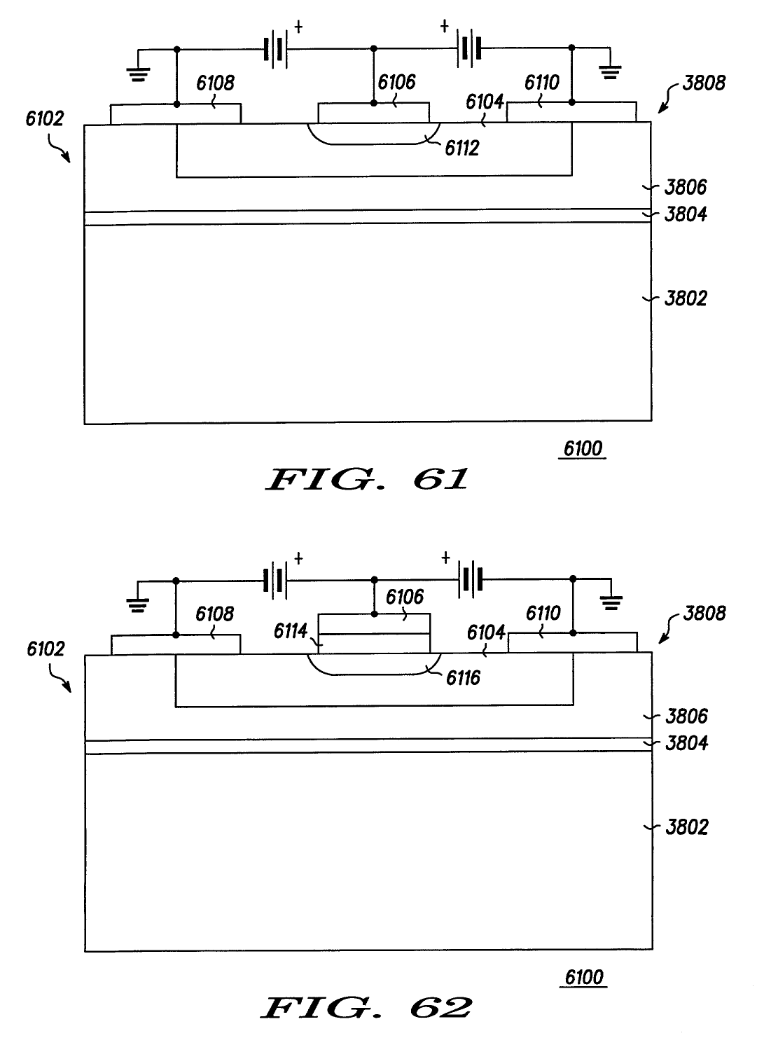

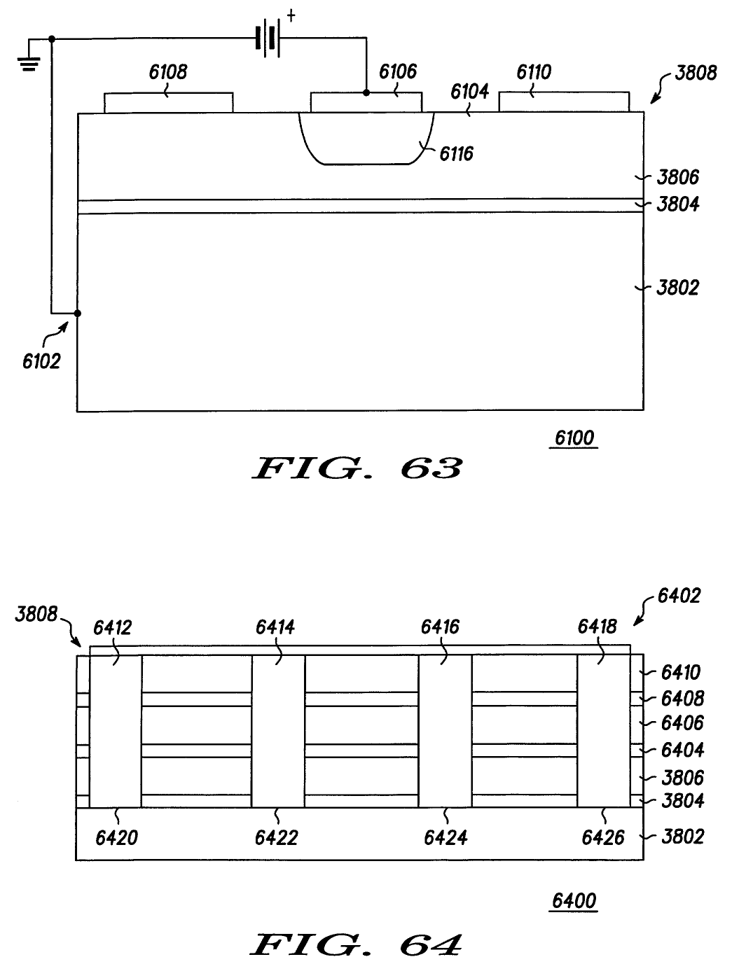

FIG. 61, FIG. 62 and FIG. 62 show cross-sections of embodiments of a semiconductor structure 6100 including a variable impedance transmission line 6102. The semiconductor structure 6100 includes a monocrystalline silicon substrate 3802, a buffer layer 3804 and a monocrystalline compound semiconductor layer 3806. The semiconductor structure 6100 may be formed in accordance with any of the embodiments described herein. A metallization layer 3808 is formed on the monocrystalline compound semiconductor material 3806.

In the embodiments of FIG. 61 and FIG. 62, the monocrystalline semiconductor material 3806 includes a doped portion 6104. Further, the metallization layer 3808 is patterned to define a center conductor 6106 and two outer conductors 6108, 6110, adjacent to the center conductor 6106 on opposing sides of the center conductor 6106. As illustrated in the figures, a DC bias voltage may be applied between the outer conductors 6108, 6110 and the center conductor 6106.

In the embodiment of FIG. 61, the metallization layer 3808 for the center conductor 6106 is formed directly on the monocrystalline compound semiconductor material surface 6112 in the region of the doped compound material 6104. The resulting contact forms a Schottky junction between the metallization 3808 the doped compound semiconductor material 6104. In the embodiment of FIG. 61, a dielectric material 6114 is deposited over a portion of the doped semiconductor material 5104 prior to formation of the metallization layer 3808 for the center conductor 6106. The dielectric 6114 may be any suitable non-conducting material, such as silicon dioxide which will form a metal oxide semiconductor (MOS) junction between the signal line of the center conductor 6106 and the compound semiconductor material 6104.

Application of the bias voltages in the embodiments of FIGS. 61, 62 produces a depletion region 6116 in the doped compound semiconductor material 6104. The bias voltage may be varied to vary the electrical characteristics of the variable impedance transmission line 6102. The capacitance experience by the center conductor 6106 will vary depending on the size of the depletion region 6116, which in turn varies in response to the applied voltage. Substrate conductivity and dielectric loss factors may also be varied by variation of the applied bias voltage. In the case of the Schottky junction of FIG. 61, some conduction may occur between the signal line of the center conductor 6106 and the grounded doped compound semiconductor material 6104. In the embodiment of FIG. 63, a bias voltage is applied between the center conductor 6106 and the silicon substrate 3802. In this embodiment, the silicon substrate 3802 includes a relatively highly conductive silicon. This may be achieved by using a highly conductive bulk silicon wafer for forming the semiconductor structure 6100 of FIG. 63 or by localized doping in the region of the variable impedance transmission line 6102. The applied bias voltage creates a depletion region 6116 in the doped compound semiconductor material 6104. Again, by varying the DC-bias between the center conductor 6106 and the silicon substrate 3802, the electrical characteristics of the variable impedance transmission line may be varied. As noted, the capacitance seen by the center conductor may be varied, and thus the transmission line impedance may be varied. Other electrical factors may be varied as well.

FIG. 64 is a cross section of a semiconductor structure 6400 including a vertical four-way combiner 6402. The semiconductor structure 6400 includes a monocrystalline silicon substrate 3802, a buffer layer 3804 and a monocrystalline compound semiconductor material layer 3806. In addition, the semiconductor structure 6400 includes a buffer layer 6404 formed on the monocrystalline compound semiconductor material layer 3806, a silicon layer 6406 formed on the buffer layer 6404, a buffer layer 6408 formed on the silicon layer 6406 and a monocrystalline compound semiconductor layer 6410 formed on the buffer layer 6408. Preferably the buffer layers 6404, 6408 serve to form accommodating buffer layers. For example, a monocrystalline oxide spaced apart from the monocrystalline semiconductor layer below by an amorphous interface layer of silicon oxide so that the accommodating buffer layer is latticed matched to both the underlying monocrystalline semiconductor material and the overlie monocrystalline semiconductor material.

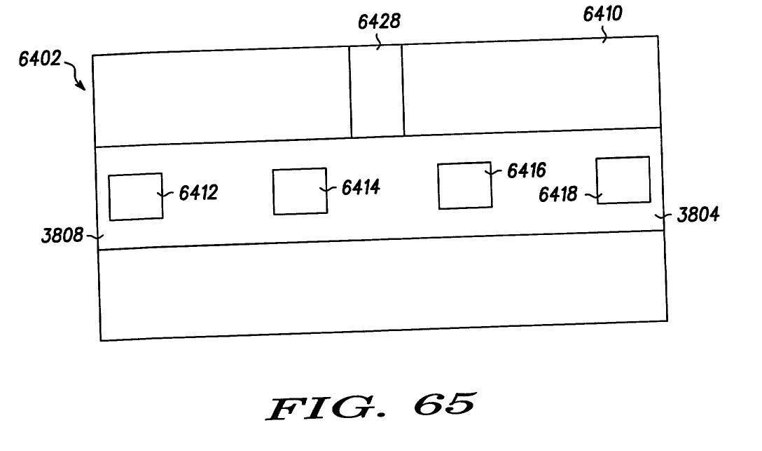

A top layer metallization 3808 is formed on the top of the monocrystalline compound semiconductor material layer 6410. Two or more vias 6412, 6414, 6416, 6418 are formed in the semiconductor structure 6400. The vias extend and electrically couple the top layer metallization 3808 and device terminals of the silicon substrate 3802. In the illustrated embodiment, the via 6412 electrically couples the top layer metallization and a drain 6420 of a first field effect transistor in the silicon layer 3802. The via 6414 electrically couples the top layer metallization 3808 and a drain 6422 of a field effect transistor. The via 6416 electrically covers the top layer metallization 3808 and a drain 6424 of a field effect transistor. The via 6418 electrically couples the top layer metallization 3808 and a drain 6426 of a field effect transistor. As can be seen in FIG. 65, the top layer metallization 3808 electrically shorts the vias 6412, 6414, 6416, 6418. Additional metallization 6428 is electrically coupled with the top layer metallization 3808 to provide a combined output for the drains 6420, 6422, 6424, 6426 of the field effect transistors. Thus, the vertical four-way combiner 6402 of FIGS. 64, 65, can combine field effect transistor outputs of the given stage with the top layer metallization being the output terminal. In an alternative embodiment, the field effect transistor output could be combined from each layer, that is, field effect transistors or any other suitable semiconductor device could be formed on any of the semiconductor layers, including the silicon substrate 3802, the combined semiconductor layer 3806, the silicon layer 6406 or the compound semiconductor layer 6410. By applying appropriate metallization at these layers, the vias 6412, 6414, 6416, 6418 may be electrically coupled to devices formed on these layers, with the resulting outputs combined on the top layer 3808. While FIGS. 64 and 65 show four vias and four outputs being combined, it is to be noted that any number of two or more outputs may be combined in the manner illustrated in FIGS. 64 and 65.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprnises,” “comprising,” or any other variation thereof, are intended to cover a nonexclusive inclusion, such that a process, method, article, or apparatus that comprises a list of elements does not include only those elements but may include other elements not expressly listed or inherent to such process, method, article, or apparatus.

We claim:

1. A semiconductor structure comprising:
a monocrystalline silicon substrate;
an amorphous oxide material overlying the monocrystalline silicon substrate on a first side of the monocrystalline silicon substrate;
a monocrystalline perovskite oxide material overlying the amorphous oxide material;
a monocrystalline compound semiconductor material overlying the monocrystalline perovskite oxide material;
a microstrip conductor overlying the monocrystalline compound semiconductor material; and
ground plane metallization overlying the monocrystalline silicon substrate on a second side of the monocrystalline silicon substrate.

2. The semiconductor structure of claim 1 further comprising:
a dielectric layer disposed between the microstrip conductor and the monocrystalline compound semiconductor material.

3. A process for fabricating a semiconductor structure, the process comprising:
providing a monocrystalline silicon substrate;
depositing a monocrystalline perovskite oxide film overlying the monocrystalline silicon substrate on a first side of the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a metallization layer on the monocrystalline compound semiconductor layer;
patterning the metallization layer to define a microstrip transmission line; and
forming a ground plane metallization layer on a second side of the monocrystalline silicon substrate.

4. The process of claim 3 further comprising:
depositing a relatively low-loss dielectric material on the monocrystalline compound semiconductor layer prior to forming a metallization layer; and
patterning the dielectric material with the metallization layer

5. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a metallic conductor layer overlying the monocrystalline compound semiconductor material and patterned to define a coplanar waveguide.

6. The semiconductor structure of claim 5 wherein the metallic conductor layer is patterned to define a center conductor and laterally adjacent ground conductors.

7. The semiconductor structure of claim 5 wherein at least a portion of the monocrystalline silicon substrate has a relatively high resistivity.

8. The semiconductor structure of claim 5 further comprising a monocrystalline silicon layer formed over a portion of the monocrystalline silicon substrate, the monocrystalline silicon layer having a relatively high resistivity, the patterned metallic conductor layer overlying the monocrystalline silicon layer.

9. The semiconductor structure of claim 5 further comprising:
a dielectric material having a relatively high dielectric constant overlying the metallic conductor layer.

10. The semiconductor structure of claim 9 further comprising:
ground plane metallization overlying the dielectric material.

11. A process for fabricating a semiconductor structure, the process comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a metallization layer on the monocrystalline compound semiconductor layer; and
patterning the metallization layer to define a coplanar waveguide.

12. The process of claim 11 wherein patterning the metallization layer comprises:
defining a center conductor; and
defining ground conductors on each of a first side and a second of the center conductor.

13. The process of claim 11 further comprising depositing a dielectric material having relatively low dielectric constant on the metallization layer after patterning the metallization layer.

14. The process of claim 13 further comprising forming a ground plane metallization layer on the dielectric material.

15. A semiconductor structure comprising:
a monocrystalline silicon substrate;
an amorphous oxide material overlying at least a relatively high resistivity portion of the monocrystalline silicon substrate;
a monocrystalline perovskite oxide material overlying the amorphous oxide material;
a monocrystalline compound semiconductor material overlying the monocrystalline perovskite oxide material;
a metallic ground conductor layer overlying the monocrystalline compound semiconductor material and patterned to define two parallel ground conductors;
a dielectric material formed between the two parallel ground conductors; and
a metallic signal conductor layer overlying a portion of the dielectric material.

16. A process for fabricating a semiconductor structure, the process comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a ground conductor metallization layer on the monocrystalline compound semiconductor layer;
patterning the ground conductor metallization layer to define parallel ground conductors;
depositing a dielectric material on the monocrystalline compound semiconductor layer between the parallel ground conductors;
forming a signal conductor metallization layer on the dielectric material; and
patterning the signal conductor metallization layer to define a signal conductor.

17. A semiconductor structure comprising:
a monocrystalline silicon substrate;
an amorphous oxide material overlying at least a relatively high resistivity portion of the monocrystalline silicon substrate;
a monocrystalline perovskite oxide material overlying the amorphous oxide material;
a monocrystalline compound semiconductor material overlying the monocrystalline perovskite oxide material;
a dielectric material overlying the monocrystalline compound semiconductor material; a metallic layer overlying the dielectric material and patterned to define two parallel ground conductors and a central signal conductor.

18. A process for fabricating a semiconductor structure, the process comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
depositing a dielectric material on the monocrystalline compound semiconductor layer; forming a metallization layer on the dielectric material; and
patterning the metallization layer to define parallel ground conductors and a center signal conductor.

19. A semiconductor structure comprising:
a monocrystalline silicon substrate;
an amorphous oxide material overlying at least a high-conductivity silicon portion of the monocrystalline silicon substrate;
a monocrystalline perovskite oxide material overlying the amorphous oxide material;
a monocrystalline compound semiconductor material overlying the monocrystalline perovskite oxide material;
a metallic conductor layer overlying the monocrystalline compound semiconductor material and patterned to define a center conductor and two associated ground conductors distanced from the center conductor by dielectric spaces; and
relatively high-dielectric constant dielectric bricks filling voids in the monocrystalline compound semiconductor material underlying the dielectric spaces.

20. A process for fabricating a semiconductor structure, the process comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
defining dielectric bricks filled with a relatively high dielectric constant dielectric material in the monocrystalline compound semiconductor layer. forming a metallization layer on the monocrystalline compound semiconductor layer and the dielectric bricks; and
patterning the metallization layer to define a center conductor and two adjacent ground conductors distanced from the center conductor by dielectric spaces over the dielectric bricks.

21. The process of claim 20 wherein defining dielectric bricks comprises:
etching portions of the metallization layer to define the dielectric spaces;
removing the monocrystalline compound semiconductor layer exposed by the etched portions of the metallization layer to define trenches; and
filling the trenches with the relatively high dielectric constant dielectric material.

22. A semiconductor structure comprising:
a monocrystalline silicon substrate having a thickness;
a relatively low-loss dielectric portion defined in the monocrystalline silicon substrate and extending substantially the thickness of the monocrystalline silicon substrate;
an amorphous oxide material overlying the monocrystalline silicon substrate and the dielectric portion on a first side of the monocrystalline silicon substrate;
a monocrystalline perovskite oxide material overlying the amorphous oxide material;
a monocrystalline compound semiconductor material overlying the monocrystalline perovskite oxide material;
a microstrip conductor overlying the monocrystalline compound semiconductor material at the dielectric portion; and
ground plane metallization overlying the monocrystalline silicon substrate on a second side of the monocrystalline silicon substrate.

23. A process for fabricating a semiconductor structure, the process comprising:
providing a monocrystalline silicon substrate;
defining a dielectric portion of the monocrystalline silicon substrate filled with a relatively low-loss dielectric material;
depositing a monocrystalline perovskite oxide film overlying the monocrystalline silicon substrate including the dielectric portion on a first side of the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a metallization layer on the monocrystalline compound semiconductor layer;
patterning the metallization layer to define a microstrip transmission line adjacent the dielectric portion; and
forming a ground plane metallization layer on a second side of the monocrystalline silicon substrate.

24. A semiconductor structure comprising:
a monocrystalline silicon substrate having a thickness;
a relatively low-loss dielectric portion defined in the monocrystalline silicon substrate and extending substantially the thickness of the monocrystalline silicon substrate;
a microstrip conductor overlying at least a portion of the dielectric portion;
an amorphous oxide material overlying the monocrystalline silicon substrate, the microstrip conductor and the dielectric portion on a first side of the monocrystalline silicon substrate;
a monocrystalline perovskite oxide material overlying the amorphous oxide material;
a monocrystalline compound semiconductor material overlying the monocrystalline perovskite oxide material; and
ground plane metallization overlying the monocrystalline silicon substrate on a second side of the monocrystalline silicon substrate.

25. The semiconductor structure of claim 24 further comprising:
a second relatively low-loss dielectric portion defined in the monocrystalline silicon substrate adjacent the dielectric portion;
a second microstrip conductor overlying at least a portion of the second dielectric portion; and
a shielding wall of conductive silicon between the dielectric portion and the second dielectric portion.

26. A process for fabricating a semiconductor structure, the process comprising:
providing a monocrystalline silicon substrate;
defining a dielectric portion of the monocrystalline silicon substrate filled with a relatively low-loss dielectric material;
forming a microstrip conductor overlying at least a portion of the dielectric portion;
depositing a monocrystalline perovskite oxide film overlying the monocrystalline silicon substrate including the dielectric portion and the microstrip conductor on a first side of the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film; and
forming a ground plane metallization layer on a second side of the monocrystalline silicon substrate.

27. The process of claim 26 further comprising:
defining a second dielectric portion of the monocrystalline silicon substrate filled with a relatively low-loss dielectric material, the second dielectric portion being adjacent the dielectric portion;
forming a shielding wall of conductive silicon between the dielectric portion and the second dielectric portion; and
forming a second microstrip conductor overlying at least a portion of the second dielectric portion.

28. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a stripling conductor overlying the monocrystalline compound semiconductor material;
a compound semiconductor dielectric material overlying the stripling conductor and the monocrystalline compound semiconductor material; and
ground plane metallization overlying the compound semiconductor dielectric material.

29. The semiconductor structure of claim 28 further comprising:
an isolating compound semiconductor dielectric material overlying the monocrystalline compound semiconductor material, the a stripling conductor overlying the isolating compound semiconductor dielectric material.

30. A process for fabricating a semiconductor structure, the process comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a metallization layer on the monocrystalline compound semiconductor layer;
patterning the metallization layer to define a stripling conductor;
forming a compound semiconductor dielectric material overlying the stripling conductor and the monocrystalline compound semiconductor layer;
forming a ground plane metallization layer overlying the compound semiconductor dielectric material.

31. The process of claim 30 further comprising:
forming an isolating compound semiconductor dielectric material overlying the monocrystalline compound semiconductor material; and
forming the metallization layer on the isolating compound semiconductor dielectric material.

32. A semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
a first relatively low dielectric constant dielectric material overlying the monocrystalline compound semiconductor material;
a stripling conductor overlying the first relatively low dielectric constant dielectric material;
a second relatively low dielectric constant dielectric material overlying the stripling conductor and the first relatively low dielectric constant dielectric material;
a compound semiconductor dielectric material overlying the second relatively low dielectric constant dielectric material; and
ground plane metallization overlying the compound semiconductor dielectric material.

33. A process for fabricating a semiconductor structure, the process comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between the monocrystalline perovskite oxide film and the monocrystalline silicon substrate;
epitaxially forming a monocrystalline compound semiconductor layer overlying the monocrystalline perovskite oxide film;
forming a first relatively low dielectric constant dielectric material overlying the monocrystalline compound semiconductor material;
forming a metallization layer on the first relatively low dielectric constant dielectric material;
patterning the metallization layer to define a stripling conductor;
forming a second relatively low dielectric constant dielectric material overlying the stripling conductor and the first relatively low dielectric constant dielectric material;
forming a compound semiconductor dielectric material overlying second relatively low dielectric constant dielectric material; and
forming a ground plane metallization layer overlying the compound semiconductor dielectric material.

34. A semiconductor structure comprising:
a monocrystalline silicon substrate;
a waveguide portion extending substantially through the monocrystalline silicon substrate, the waveguide portion filled with a relatively low dielectric constant dielectric material;
conductive silicon sidewall portions of the monocrystalline silicon substrate on opposing sides of the waveguide portion;
an amorphous oxide material overlying the monocrystalline silicon substrate including the waveguide portion and the conductive silicon sidewall portions;
a monocrystalline perovskite oxide material overlying the amorphous oxide material;
a monocrystalline compound semiconductor material overlying the monocrystalline perovskite oxide material;
interconnect metallization disposed on the monocrystalline compound semiconductor material;
a metal-filled via in electrical contact with the interconnect metallization and extending through the amorphous oxide material, the monocrystalline perovskite oxide material and the monocrystalline compound semiconductor material into the waveguide portion.

35. A semiconductor structure operable as a trapped image line, the semiconductor structure comprising:
a monocrystalline silicon substrate;
a dielectric substrate portion filled with a relatively low dielectric constant dielectric material and extending substantially through the monocrystalline silicon substrate;
an amorphous oxide material overlying the monocrystalline silicon substrate and the dielectric substrate portion on a first side of the monocrystalline silicon substrate;
a monocrystalline perovskite oxide material overlying the amorphous oxide material;
a monocrystalline compound semiconductor material overlying the monocrystalline perovskite oxide material;
first and second dielectric side walls on opposing sides of a waveguide portion of the monocrystalline compound semiconductor material, the first and second dielectric side walls being formed of a relatively low dielectric constant dielectric material and extending through the amorphous oxide material and the monocrystalline perovskite oxide material to be in electrical contact with the dielectric substrate portion;
side vias extending through the amorphous oxide material and the monocrystalline perovskite oxide material and the monocrystalline silicon substrate on opposing sides of the dielectric substrate portion;
a top metallization layer overlying the waveguide portion of the monocrystalline compound semiconductor material on a first side of the semiconductor structure and in electrical contact with the side vias; and
a metallic ground plane on a second side of the semiconductor structure and in electrical contact with the side vias.

36. A semiconductor structure operable as a coaxial wave guide, the semiconductor structure comprising:
a monocrystalline silicon substrate;
a dielectric substrate portion filled with a relatively low dielectric constant dielectric material and extending substantially through the monocrystalline silicon substrate;
a center conductor within the dielectric substrate portion;
an amorphous oxide material overlying the monocrystalline silicon substrate and the dielectric substrate portion on a first side of the monocrystalline silicon substrate;
a monocrystalline perovskite oxide material overlying the amorphous oxide material;
a monocrystalline compound semiconductor material overlying the monocrystalline perovskite oxide material;
side vias extending through the amorphous oxide material, the monocrystalline perovskite oxide material, the monocrystalline compound semiconductor material and the monocrystalline silicon substrate;
top metallization overlying the monocrystalline compound semiconductor material in electrical contact with the side vias; and
bottom metallization overlying the monocrystalline silicon substrate in electrical contact with the side vias.

37. A semiconductor structure operable as a coaxial wave guide, the semiconductor structure comprising:
a monocrystalline silicon substrate including
a center conductor portion,
an outer conductor portion surrounding the center conductor portion,
a dielectric region spacing the center conductor portion and the outer conductor portion, and
dielectric standoffs separating the center conductor portion and the outer conductor portion;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material.

38. A semiconductor structure operable as a coaxial wave guide, the semiconductor structure comprising:
a monocrystalline silicon substrate including silicon portions spaced by at least one dielectric portion, the at least one dielectric portion extending substantially through the monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material;
normal vias extending normally from a first surface of the semiconductor structure to a second surface of the semiconductor structure between the silicon portions and a dielectric portion;
diagonal vias extending from the first surface of the semiconductor structure to the second surface of the semiconductor structure;
top metallization overlying the monocrystalline compound semiconductor material and in electrical contact with the normal vias and the diagonal vias; and
bottom metallization overlying the silicon portions and the at least one dielectric portion, the bottom metallization being in electrical contact with the normal vias and the diagonal vias.

39. A semiconductor structure operable as a coaxial waveguide, the semiconductor structure comprising:
a monocrystalline silicon substrate;
an amorphous oxide material overlying the monocrystalline silicon substrate;
a monocrystalline perovskite oxide material overlying the amorphous oxide material;
a monocrystalline compound semiconductor material overlying the monocrystalline perovskite oxide material; and
a coaxial waveguide portion including
a void formed through the amorphous oxide material, the monocrystalline perovskite oxide material and the monocrystalline compound semiconductor material and extending substantially through the monocrystalline silicon substrate,
outer conductor metallization on an inner surface of the void,
inner conductor metallization, and
a dielectric material spacing the outer conductor metallization and the inner conductor metallization.

40. The semiconductor structure of claim 39 further comprising:
a first contacting portion on a first side of the monocrystalline silicon substrate; and
a second contacting portion on a second side of the monocrystalline silicon substrate.

41. The semiconductor structure of claim 40 wherein the first contacting portion comprises:
interconnect metallization in electrical contact with the inner conductor metallization; and
a dielectric material isolating the interconnect metallization and the outer conductor metallization.

42. The semiconductor structure of claim 40 wherein the second contacting portion comprises:
first solder bumps in electrical contact with the inner conductor metallization; and
second solder bumps in electrical contact with the outer conductor metallization.

43. The semiconductor structure of claim 40 further comprising:
bottom metallization overlying the monocrystalline silicon substrate on the second side of the monocrystalline silicon substrate; and
third solder bumps in electrical contact with the bottom metallization.

44. A semiconductor structure operable as a variable impedance transmission line, the semiconductor structure comprising:
a monocrystalline silicon substrate;
a buffer layer including
an amorphous oxide material overlying the monocrystalline silicon substrate, and
a monocrystalline perovskite oxide material overlying the amorphous oxide material;
a monocrystalline compound semiconductor material overlying the monocrystalline perovskite oxide material;
a doped compound semiconductor portion formed in the monocrystalline compound semiconductor material;
a conductor overlying the doped compound semiconductor portion.

45. The semiconductor structure of claim 44 further comprising one or more ground conductors adjacent the conductor.

46. A semiconductor structure of claim 44 wherein the conductor and the monocrystalline compound semiconductor material form a Schottky junction.

47. A semiconductor structure of claim 44 wherein the conductor is a metallic conductor, the semiconductor structure further comprising a dielectric layer formed between the conductor and the monocrystalline compound semiconductor material to form a metal-oxide-semiconductor junction.

48. A semiconductor structure of claim 44 wherein the monocrystalline silicon substrate is doped to be relatively highly conductive, forming a semiconductor-oxide-semiconductor junction between the doped compound semiconductor material, the buffer layer and the doped monocrystalline silicon substrate.

49. A semiconductor structure operable as a signal combiner, the semiconductor structure comprising:
a monocrystalline silicon substrate;
a buffer layer including
an amorphous oxide material overlying the monocrystalline silicon substrate, and
a monocrystalline perovskite oxide material overlying the amorphous oxide material;
a monocrystalline compound semiconductor material overlying the monocrystalline perovskite oxide material;
two or more doped silicon portions forming terminals of silicon devices;
two or more vias extending through the monocrystalline compound semiconductor material, the monocrystalline perovskite oxide material and the amorphous oxide material, each respective via in electrical contact at one end of the respective via with an associated doped silicon portion; and
interconnect metallization electrically coupling the two or more vias to combine signals associated with the silicon devices.

50. The semiconductor structure of claim 49 further comprising
a second buffer layer;
a silicon layer formed on the a monocrystalline compound semiconductor material;
a third buffer layer; and
a second layer of monocrystalline compound semiconductor material, the two or more vias extending through the second buffer layer, the silicon layer, the third buffer layer and the second layer of monocrystalline compound semiconductor material.

51. The semiconductor structure of claim 50 further comprising one or more doped silicon portions of the silicon layer forming terminals of additional silicon devices, each of the one or more doped silicon portions in electrical contact with a respective via.
